(19) United States
(12) Patent Application Publication
(10) Pub. No.: US 2008/0108215 A1
(43) Pub. Date: May 8, 2008

(54) INTEGRATED CIRCUIT INTERCONNECT LINES HAVING REDUCED LINE RESISTANCE

(75) Inventor: Suketu A. Parikh, San Jose, CA (US)

Correspondence Address: APPLIED MATERIALS, INC., P. O. BOX 450A, SANTA CLARA, CA, 95052, US

(73) Assignee: APPLIED MATERIALS, INC.

(21) Appl. No.: 11/557,438

(22) Filed: Nov. 7, 2006

(51) Int. Cl. H01L 21/44

(52) U.S. Cl. 438/597

(57) ABSTRACT

The present invention provides integrated circuit fabrication methods and devices wherein shunted interconnect lines are formed. The shunted interconnect lines are formed in a dielectric stack comprising (1) a first dielectric layer having dense interconnect lines that form a first dielectric layer dense line subset and (2) a sequentially deposited (i) etch stop layer, (ii) second dielectric layer and (iii) third dielectric layer. An interconnect line trench design is prepared in the third dielectric layer. An interconnect line trench is formed in the third dielectric layer according to the interconnect line trench design. One or more electrically conductive shunts are fabricated in the second dielectric layer such that the one or more shunts (1) extend from the interconnect line trench to the etch stop layer and (2) do not cross over the first dielectric layer dense line subset.

### FIELD OF THE INVENTION

The present invention relates to integrated circuit (IC) interconnect lines employing electrically conductive interconnect line shunts for reduced resistance of interconnect lines.

### BACKGROUND OF THE INVENTION

A typical integrated circuit chip layout is prepared by employing a CAD (computer-aided design) tool to place and route cells from a library of cells and custom circuit blocks to form a complete chip layout. The internal layout data base is converted to a standard stream file format such as GDS-II, for mask making. GDS-II is available from Cadence Design Systems, located in San Jose, Calif. An electronic design automation (EDA) tool can be employed for creating the schematic circuit design. EDA tools are available from Cadence Design Systems.

Typically, an IC chip includes a semiconductor substrate and several layers that are sequentially deposited on the substrate. The CAD layout that includes the IC elements, including the library cells of a chip layer, is commonly referred to as a composite layout. A separate CAD layout is utilized to prepare a reticle/mask of the circuit pattern for each mask layer of the chip, employing conventional photolithography techniques. The CAD data format is translated to a mask writer data format in a process referred to as fracturing, wherein the CAD layout features are fractured into exposure specific data. The fractured data form the reticle mask data file. This data file is then employed to project an image of the layout on a photoresist covered reticle blank, in a process known as mask writing. Mask writing usually requires a significant write-time due to the complexities, such as optical proximity correction (OPC), and the volume of the fractured data.

Imaging of the layout, i.e. exposure of the blank, is generally executed using laser or e-beam technology. The exposed blank is subsequently developed, and etched to fabricate a reticle/mask having the circuit pattern that includes all of the required circuit elements for a particular chip layer. A typical reticle includes a glass plate having transparent and opaque regions, usually chromium, that form the IC pattern for the chip layer.

Using conventional lithography, the mask or reticle is used to project the IC pattern on a photoresist layer that is deposited on a chip layer, such as a dielectric layer. The exposed resist layer is then developed to expose areas of the chip layer that are intended to be treated or to be selectively protected, such as selectively etching a dielectric layer in order to form cavities for the subsequent fabrication of electrical contacts, vias and interconnect lines in or on the dielectric layer, or to selectively etch or protect exposure patterns of silicon in a substrate or polysilicon on a wafer substrate and to for example fabricate gate electrodes for transistors.

A semiconductor device such as an integrated circuit generally has electronic circuit elements such as transistors, diodes and resistors fabricated integrally on a single body of semiconductor material. The various circuit elements are connected through conductive connectors to form a complete circuit that can contain millions of individual circuit elements. Interconnects provide the electrical connections between the various electronic elements of an IC and they form the connections between these elements and the device's external contact elements, such as pins, for connecting the IC to other circuits. Typically, interconnect lines form horizontal connections between electronic circuit elements while conductive vias form vertical connections between the electronic circuit elements, resulting in layered connections. A variety of techniques are employed to create interconnect lines and vias. One such technique involves a process generally referred to as dual damascene, which includes forming a trench and an underlying via hole. The trench and the via hole are then simultaneously filled with a conductor material, for example a metal, thus simultaneously forming an interconnect line and an underlying via.

Multiple integrated circuits are fabricated on a layered semiconductor wafer such that these integrated circuits are designed to each have identical composition, dimensions and performance. Metallization processes, such as forming the interconnect lines, occur on the back end of the line (BEOL) of the wafer. The finished wafer is cut into sections, each section forming a die that is processed to fabricate a microchip containing the complete IC.

Horizontal interconnect lines, also known as wires, are typically formed in a trench that is fabricated by etching a dielectric layer on the BEOL. A conductive material such as copper, aluminum or metal alloys is then deposited in the trench using such deposition techniques as electrochemical plating (ECP), electroless plating and physical vapor deposition (PVD).

Advances in semiconductor materials and processing techniques have resulted in reducing the overall size of the IC elements while increasing their number on a single body of semiconductor material. Additional miniaturization is highly desirable for improved IC performance and cost reduction. Size reduction of IC elements includes reducing the diameter of interconnect lines to such an extend that the resistance and capacitance, typical of present and future interconnect lines, can for example exceed the gate delay at IC elements such as transistors. It is therefore desirable to develop IC interconnect lines suitable for meeting present and future requirements for further miniaturization wherein the interconnect lines have a reduced electrical resistance.

### SUMMARY OF THE INVENTION

In one embodiment of the present invention, novel processing methods are provided for fabricating novel IC interconnect lines having electrically conductive shunts. A dielectric stack is formed on a semiconductor substrate by (1) depositing a first dielectric layer on the semiconductor substrate and fabricating interconnect lines in the first dielectric layer that include at least two dense lines and (2) sequentially depositing (i) an etch stop layer, (ii) a second dielectric layer and (iii) a third dielectric layer, wherein (3) (i) the etch stop layer and the first dielectric layer have dissimilar etching characteristics, (ii) the second dielectric layer has dissimilar etching characteristics with respect to the etch stop layer and with respect to the first dielectric layer and (iii) the third dielectric layer has dissimilar etching characteristics with respect to the etch stop layer and with respect to the second dielectric layer.

An interconnect line trench design is prepared in the third dielectric layer wherein the line trench design crosses over the at least two dense lines. One or more dense line subsets are formed in the first dielectric layer such that the one or more dense line subsets underlay the trench design.

A first etch mask layer is deposited on the dielectric stack. Thereafter, the mask layer is developed to form etch masks that underlay the trench design but do not extend to the full length of the trench design. The etch masks do not cross over the underlying one or more dense line subsets. The etch masks are then used for etching slots through the second and third dielectric layers such that each slot is positioned at a novel tolerance space distance from the one or more dense line subsets. The first etch mask layer is removed. A sacrificial fill is subsequently deposited in the slots, followed by deposition of sacrificial overburden.

A second etch mask layer is deposited on the sacrificial overburden. The second etch mask layer is developed to form an interconnect line trench mask according to the interconnect line trench design. The interconnect line trench mask is utilized to form (1) an interconnect line cavity according to the interconnect line trench design and (2) one or more shunts slots extending from the interconnect line cavity to the etch stop layer, wherein the one or more shunt slots are positioned at a tolerance space distance from the one or more dense line subsets.

The interconnect line cavity and underlying shunt slots are simultaneously filled with a conductive material such as copper. An interconnect line that includes underlying electrically conductive shunts is thereby fabricated.

In an alternate embodiment of the present invention novel processing methods are employed for fabricating novel IC interconnect lines in the third dielectric layer wherein these lines include one or more electrically conductive shunts and additionally having a via connection between the third dielectric layer interconnect line and a first dielectric layer interconnect line. These novel interconnect lines include dual damascene structures including electrically conductive shunts that are positioned at a tolerance space distance from the one or more dense subsets.

In a further embodiment of the present invention, a novel cumulative tolerance space is employed instead of a tolerance space. A cumulative tolerance space is the sum of the tolerance space and the space that is allowed for metal process alignment.

### BRIEF DESCRIPTION OF THE DRAWINGS

FIGS. 1A-1M are schematic cross-sectional views, not to scale, illustrating an embodiment of IC structures of the present invention at sequential stages.

FIG. 1N is a schematic perspective view, not to scale, of electrically conductive components of the present invention as schematically illustrated in FIG. 1M.

FIG. 1O is a schematic plan view, not to scale, of the present invention as schematically illustrated in FIG. 1B.

FIG. 1P is a schematic plan view, not to scale, of the present invention as schematically illustrated in FIG. 1C.

FIG. 1Q is a schematic plan view, not to scale, of the present invention as illustrated in FIG. 1G.

FIG. 1R is a schematic cross-sectional view, not to scale, of the present invention as illustrated in FIG. 1Q.

FIG. 1S is a schematic cross-sectional view, not to scale, of the present invention as illustrated in FIG. 1Q.

FIG. 1T is a schematic plan view, not to scale, of the present invention as illustrated in FIG. 1L.

FIG. 1U is a schematic cross-sectional view, not to scale, of the present invention as illustrated in FIG. 1T.

FIG. 1V is a schematic cross-sectional view, not to scale, of the present invention as illustrated in FIG. 1U.

FIGS. 2A-2M are schematic cross-sectional views, not to scale, illustrating an embodiment of IC structures of the present invention at sequential stages.

FIG. 2N is a schematic perspective view, not to scale, of electrically conductive components of the present invention as schematically illustrated in FIG. 2M.

FIGS. 3A-3I are schematic cross-sectional views, not to scale, illustrating an embodiment of IC structures of the present invention at sequential stages.

FIG. 3J is a schematic perspective view, not to scale, of electrically conductive components of the present invention as schematically illustrated in FIG. 3I.

FIGS. 4A-4K are schematic cross-sectional views, not to scale, illustrating an embodiment of the present invention.

FIG. 4L is a schematic perspective view, not to scale, of electrically conductive components of the present invention as schematically illustrated in FIG. 4K.

FIGS. 5A-5D are schematic cross-sectional views, not to scale, illustrating an embodiment of the present invention.

FIG. 6 is a schematic cross-sectional view, not to scale, illustrating an embodiment of the present invention.

### DETAILED DESCRIPTION OF THE INVENTION

While describing the invention and its embodiments, certain terminology will be utilized for the sake of clarity. It is intended that such terminology includes the recited embodiments as well as all equivalents.

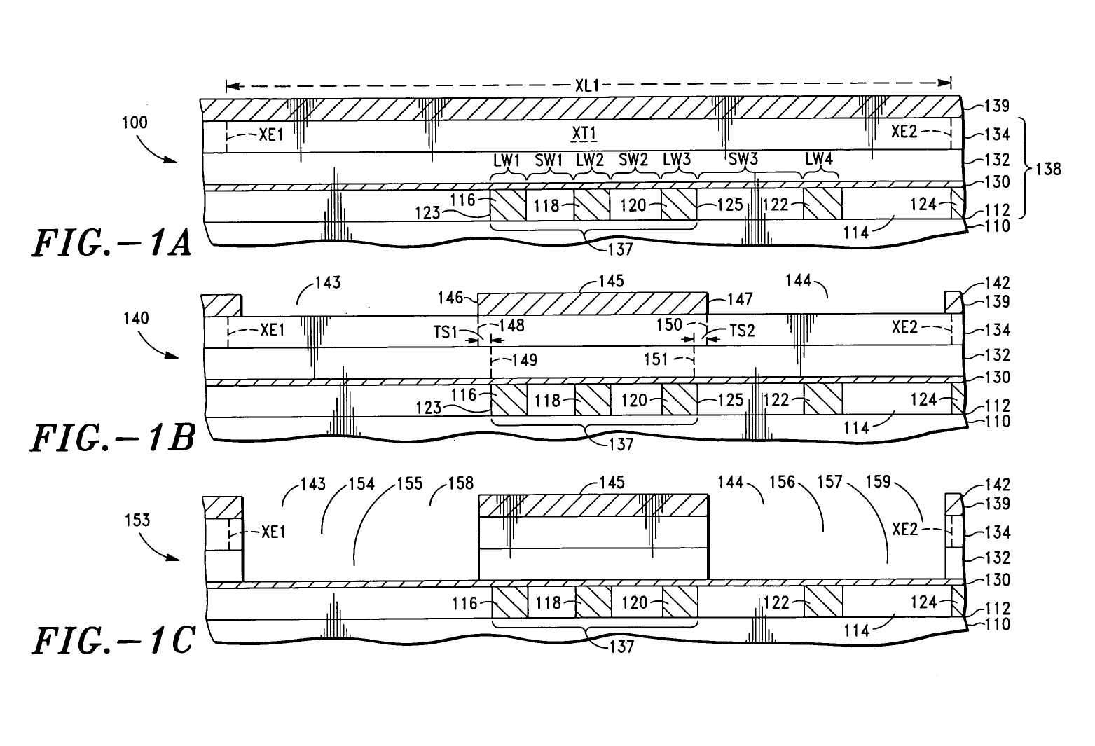

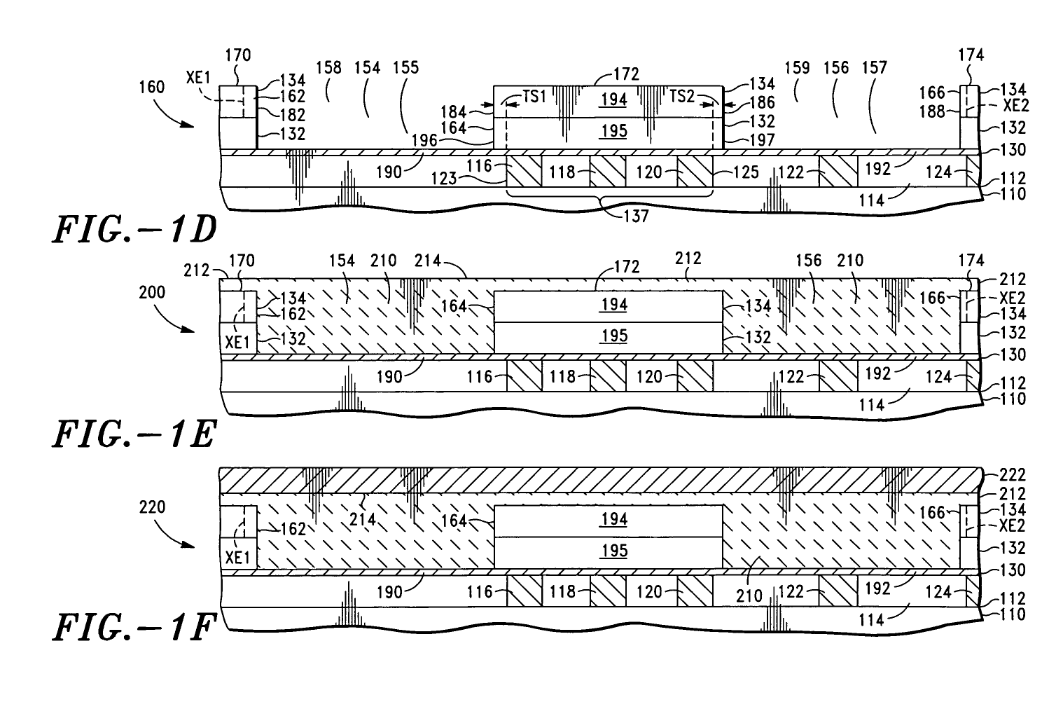

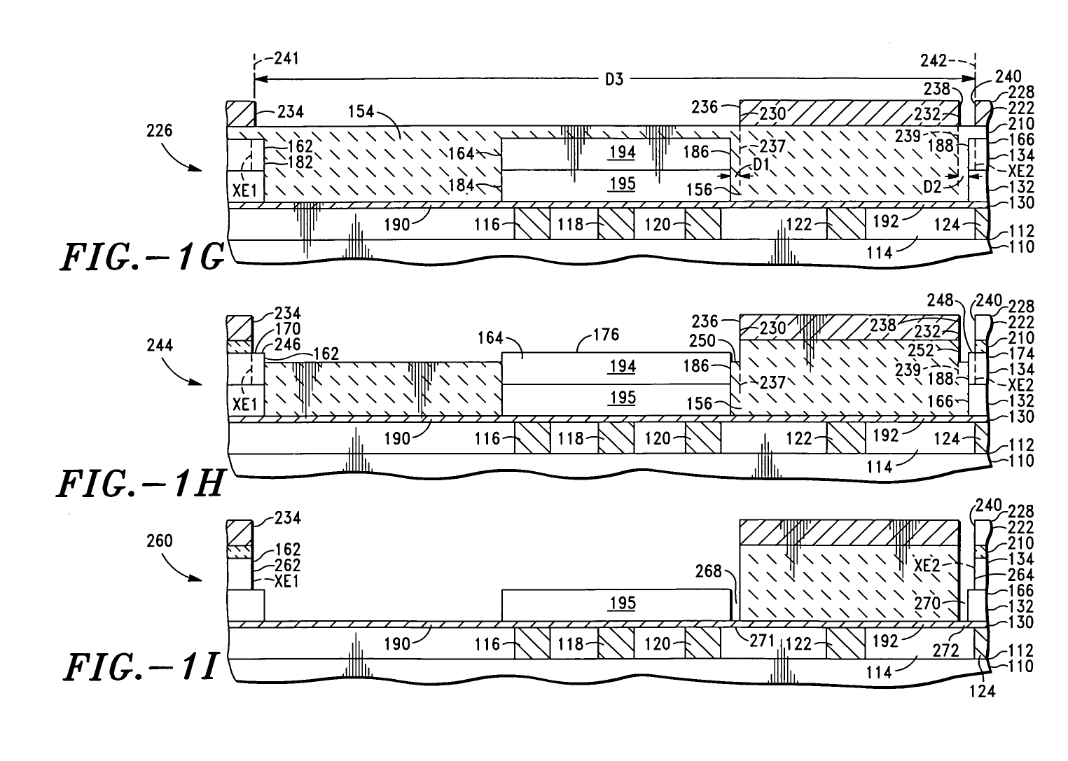

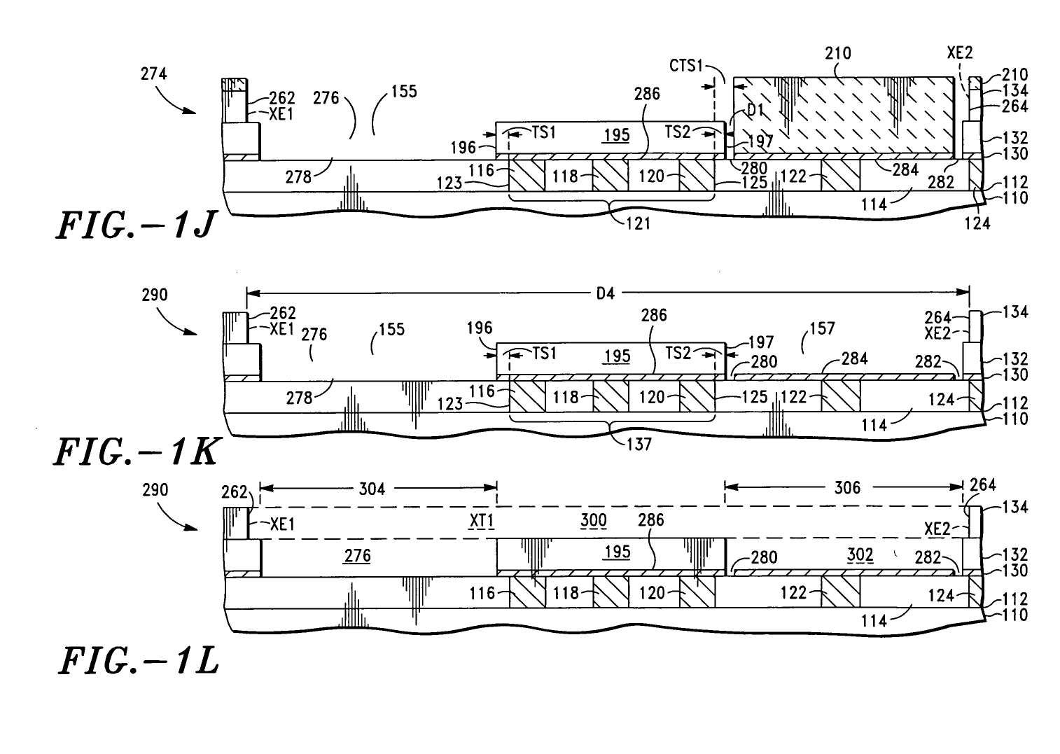

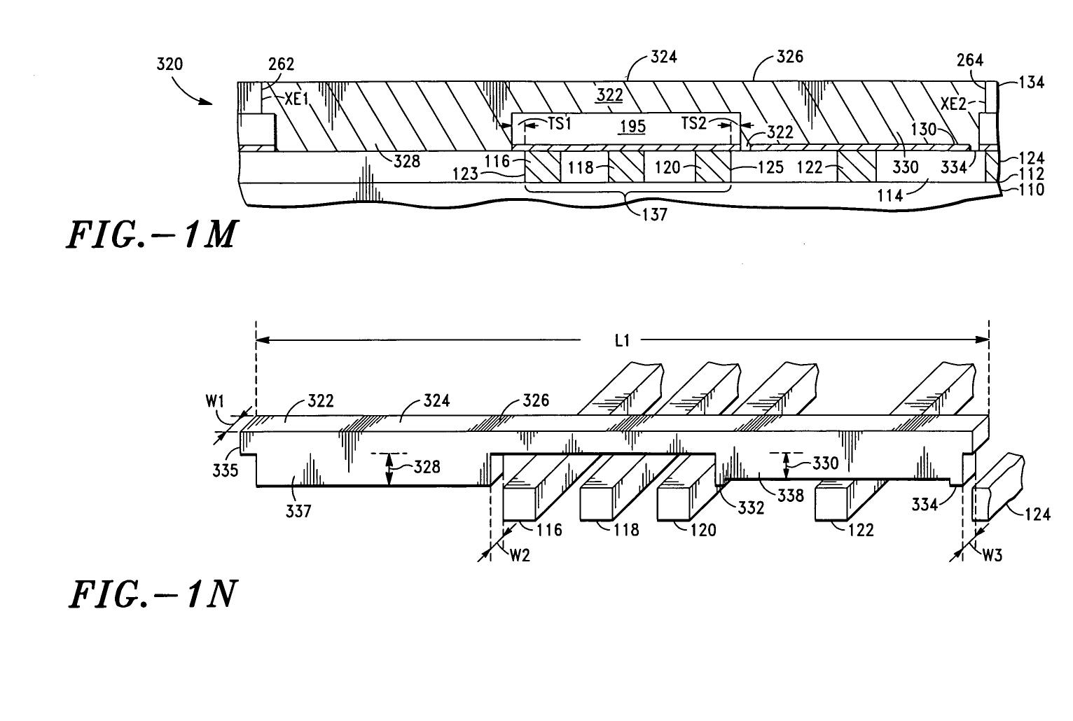

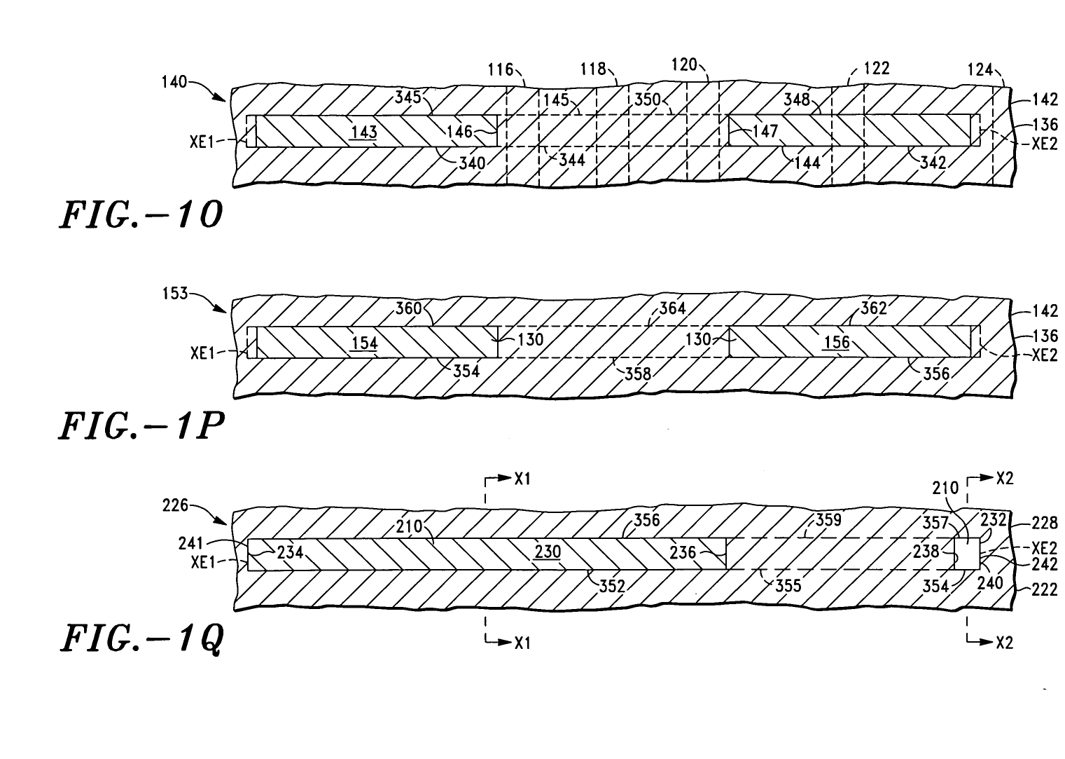

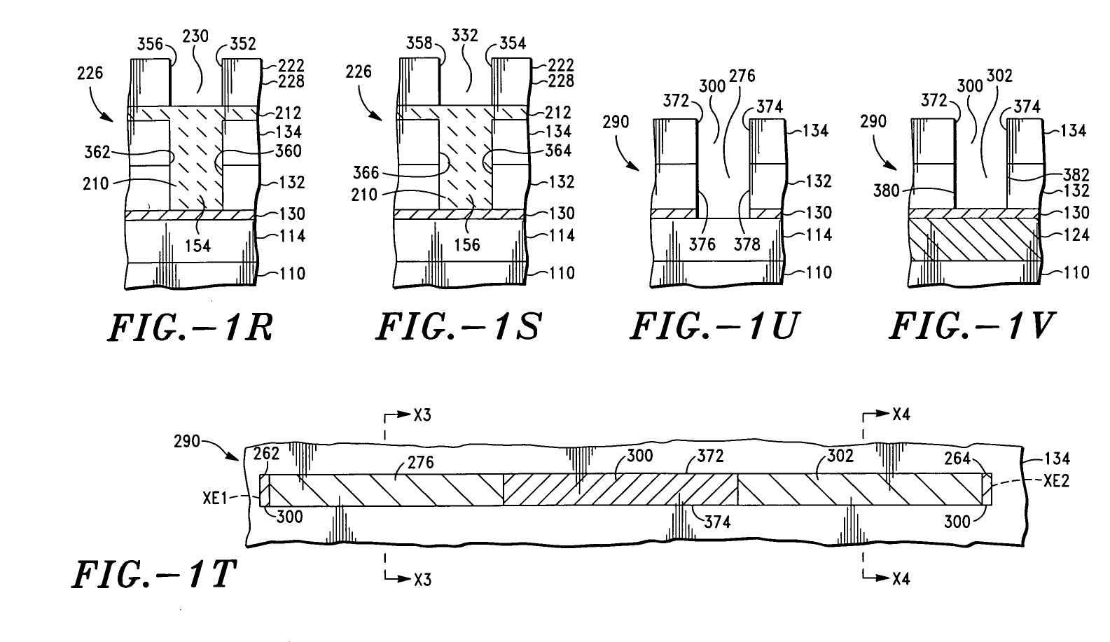

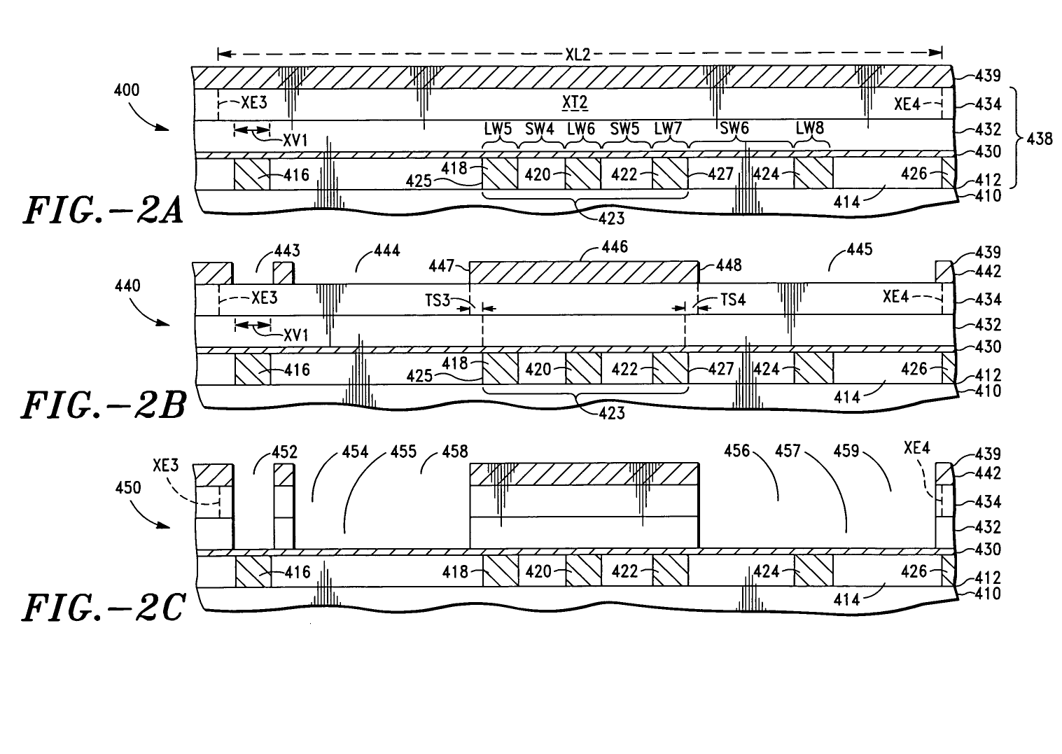

One embodiment of the invention, schematically illustrated in FIGS. 1A-1V, shows a novel processing sequence, for forming IC structures including IC structures comprising an interconnect line having electrically conductive shunts that are in alignment with the interconnect line. The expression “integrated circuit structure” as defined herein, means completely formed integrated circuits and partially formed integrated circuits.

FIG. 1A shows an IC structure 100 having a semiconductor substrate 110, including a substrate top surface 112. The expression “semiconductor substrate” as defined herein, means structures and devices comprising typical IC elements, components, interconnects and semiconductor materials. A first dielectric layer 114 is formed on top surface 112 of substrate 110. Using methods and materials known to a person of ordinary skill in the art, electrically conductive interconnect lines 116, 118, 120, 122 and 124 are fabricated in first dielectric layer 114, wherein line 124 is partly shown. Lines 116, 118, 120 and 122 are substantially parallel, see IC structure 140 illustrated in FIG. 10. Thereafter, an etch stop layer 130 shown in FIG. 1A, is deposited on first dielectric layer 114 and on interconnect lines 116, 118, 120, 122 and 124. Preferably, etch stop layer 130 has a minimum thickness that is substantially equal to 300 Å. Next, a second dielectric layer 132 is deposited on etch stop layer 130, thereafter a third dielectric layer 134 is deposited on second dielectric layer 132. It will be understood that the top surfaces of semiconductor substrate 110, first dielectric layer 114, etch stop layer 130, second dielectric layer 132 and third dielectric layer 134 are preferably planarized using conventional planarizing techniques, prior to forming a subsequent layer on each of these enumerated layers.

First dielectric layer 114 is also referred to as metallizing layer 1 (M1), while third dielectric layer 134 is also referred to as metallizing layer 2 (M2). Second dielectric layer 132 is also referred to as via layer 1 (V1). The expressions M1, M2 and V1 as used herein are known to a person of ordinary skill in the art.

With reference to IC structure 100, depicted in FIG. 1A, second and third dielectric layers 132 and 134 respectively, comprise materials having dissimilar etching characteristics. The expression “dissimilar etching characteristics” of two materials or layers as defined herein, means etching properties of these materials or layers such that one of the materials or layers has a higher etch rate than the other material in a specific etch chemistry. Etch stop layer 130 comprises materials having dissimilar etching characteristics with respect to (1) first dielectric layer 114, (2) second dielectric layer 132, and (3) third dielectric layer 134.

IC structure 100 (FIG. 1A) comprises a dielectric stack 138 that includes layers 114, 130, 132 and 134, wherein dielectric layer 114 includes interconnect lines 116, 118, 120, 122 and 124.

In the following processing sequence, dielectric stack 138 is utilized to (1) fabricate an interconnect line trench cavity having two underlying shunt cavities, that will be described and illustrated in connection with FIG. 1L, and (2) a shunted interconnect line having two underlying electrically conductive shunts which will be described and illustrated in connection with FIG. 1M.

An interconnect line trench design XT1 (FIG. 1A) is designed in third dielectric layer 134 such that trench XT1 has end surface designs XE1 and XE2. End surface designs XE1 and XE2 are designed to extend substantially vertically through layer 134. Trench design XT1 crosses over M1 lines 116, 118, 120 and 122, but does not cross over M1 line 124.

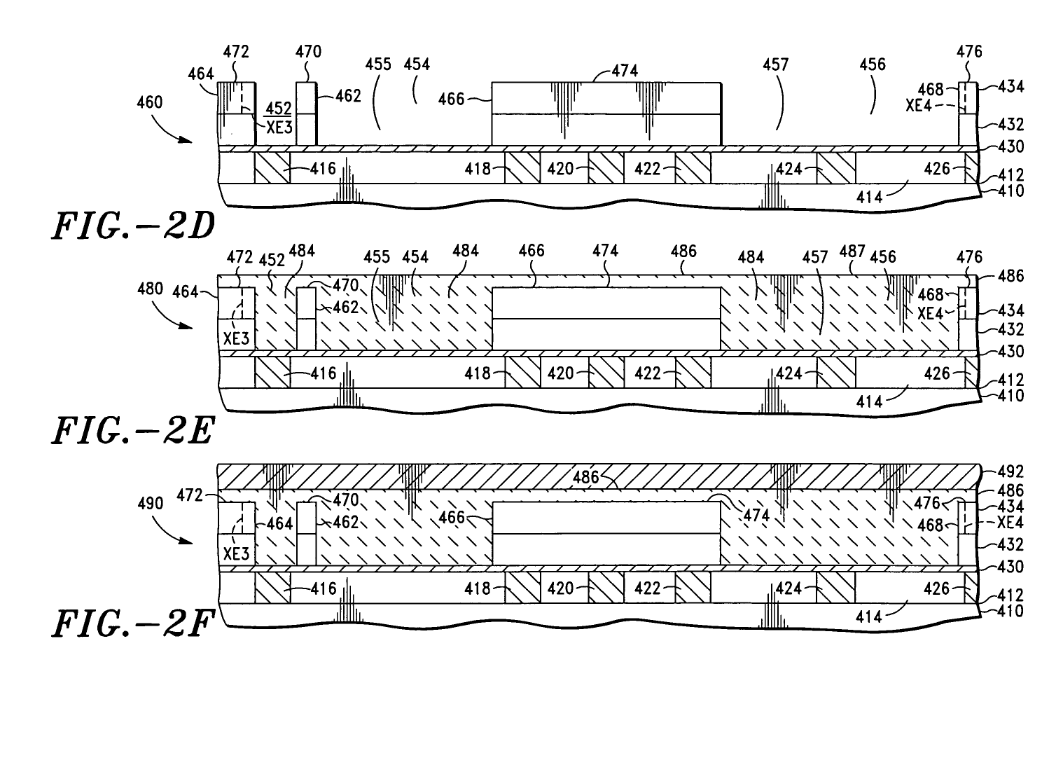

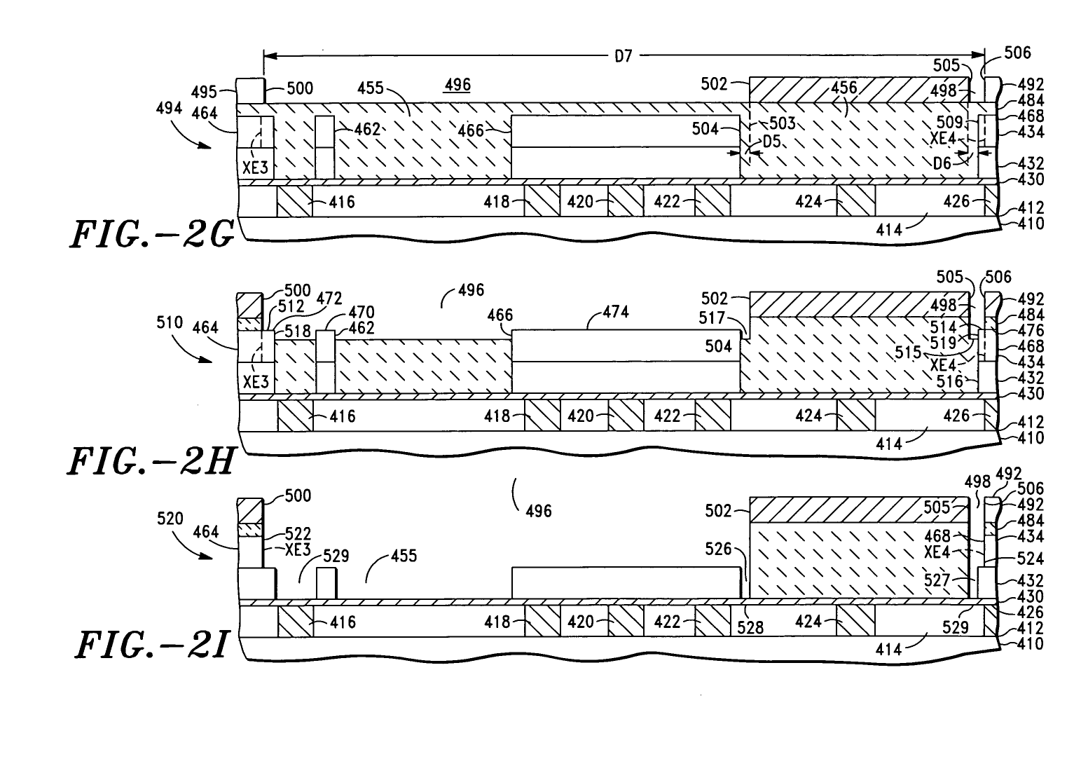

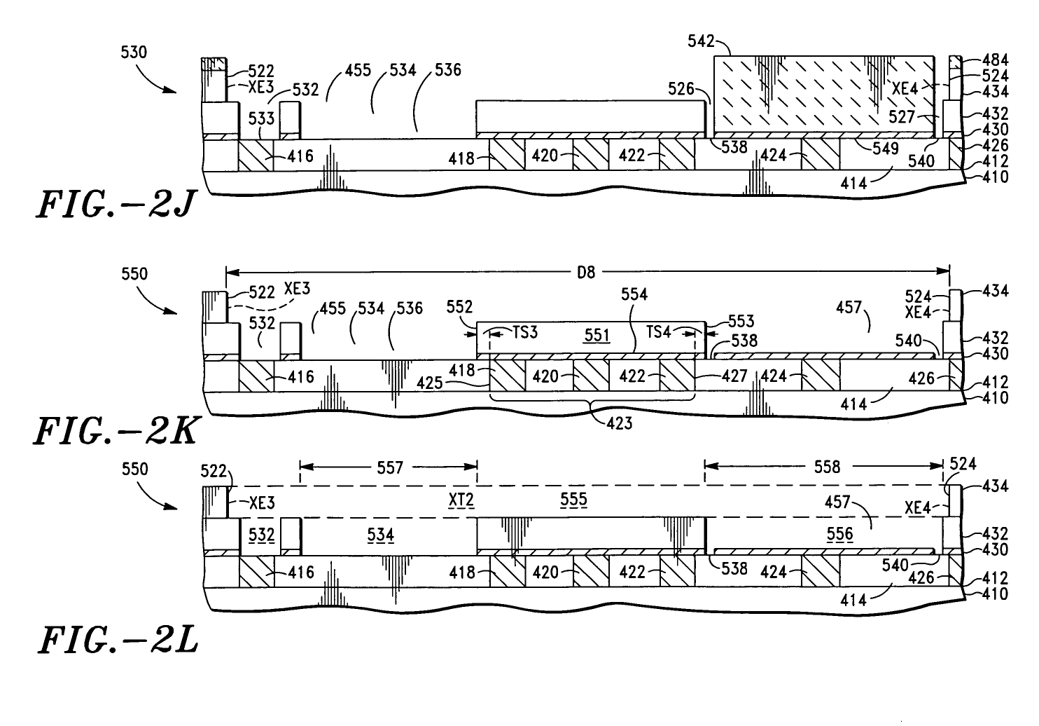

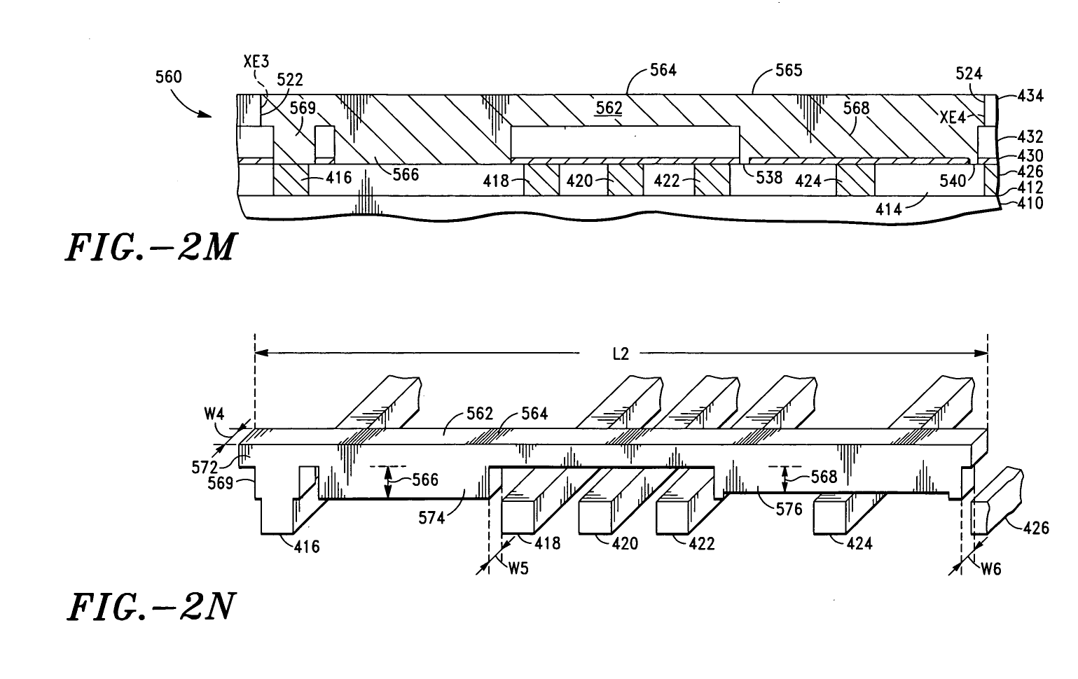

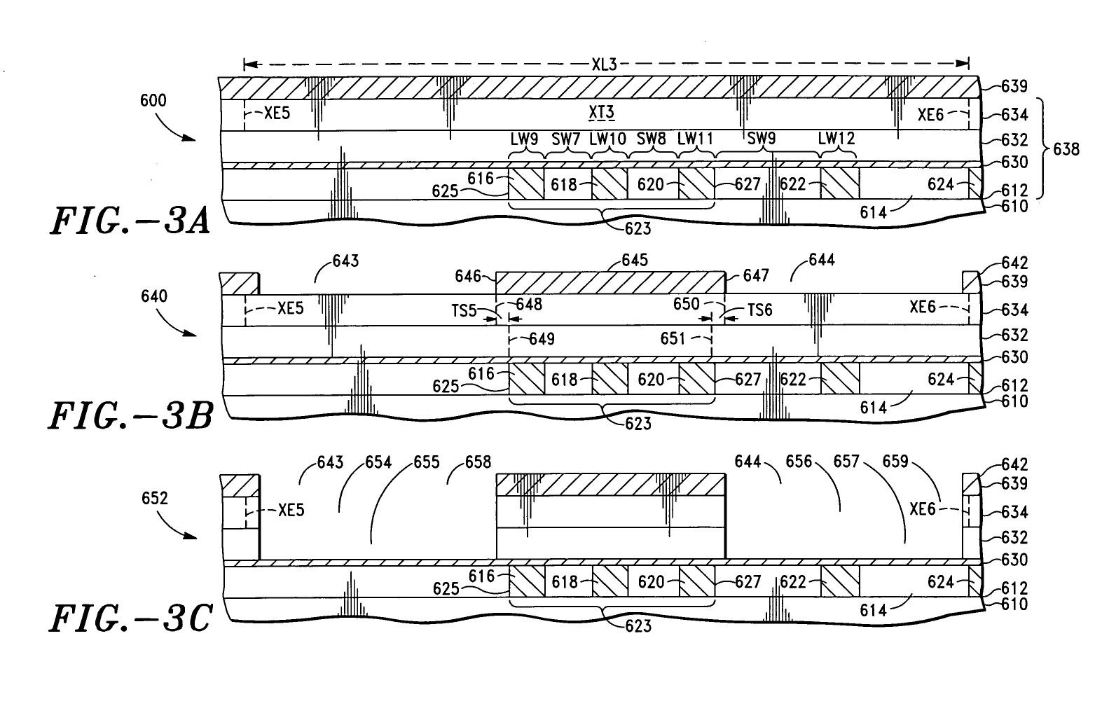

The expressions “trench-crossed M1 line” and “trench-crossed M1 lines” as used within the context of the present invention means that (1) the subject M1 line or M1 lines are crossed over by the M2 trench design and (2) that the subject M1 line or M1 lines is/are not designated as an M2-trench-connecting M1 line. The expression “M2-trench-connecting M1 line” as used within the context of the present invention means an M1 line that is designed to form a via hole connection with an M2 trench. M1 line 416 of IC structure 400, depicted in FIG. 2A, is an example of an M2-trench-connecting M1 line. M1 lines 116, 118, 120 and 122, shown in FIG. 1A, are thus designated as trench-covered M1 lines. Trench design length XL1 constitutes the length of trench design XT1, XT1, XE1, XE2 and XL1 are design elements rather than fabricated elements. Trench design XT1 is designed for fabricating an interconnect line trench cavity 300 which will be illustrated and described in connection with IC structure 290 depicted in FIG. 1L.

Employing information regarding trench design XT1 (FIG. 1A) in third dielectric layer 134, a determination is made to define which of the interconnect lines M1 lines 116, 118, 120 and 122 are isolated lines, if any, and which of these M1 lines are dense lines, if any. The expression “isolated line” as used within the context of the present invention means that the dielectric spacing between the subject line and the nearest line in the same dielectric layer is ≧5 times the line width of the subject line. The expression “dense line” as used within the context of the present invention means that the dielectric spacing between the subject interconnect line and the nearest interconnect line in the same dielectric layer is <5 times the line width of the subject line. The expression “dielectric spacing” as used within the context of the present invention means that the subject spacing is in a dielectric material. A determination regarding isolated lines and dense lines is made only where this concerns M1 lines underlying trench design XT1; M1 line 124 is therefore not included in a determination regarding isolated lines and dense lines.

For the purpose of defining interconnect lines as isolated or dense, the relevant line widths and dielectric spaces between the lines are determined as follows, as schematically shown in FIG. 1A. Line widths LW1, LW2, LW3 and LW4 indicate the line widths of interconnect lines 116, 118, 120 and 122 respectively. Similarly, (1) dielectric space width SW1 is the width in first dielectric layer 114 between lines 116 and 118, (2) dielectric space width SW2 is the width in layer 114 between lines 118 and 120, and (3) dielectric space width SW3 is the width in layer 114 between lines 120 and 122.

Where adjacent M1 lines are not parallel (not shown), the dielectric spacing between the non-parallel adjacent lines is measured at the point or region (not shown) where the lines have the smallest dielectric spacing between them. In the case where two adjacent lines differ in widths, the line having the smallest width is used in the above described determination for judging whether the adjacent lines are dense lines or isolated lines.

In the embodiment of the present invention shown in FIG. 1A, a design such as a CAD layout (not shown) or standard stream file format (not shown), e.g. GDS-II (not shown), can provide the design information regarding M1 lines 116, 118, 120 and 122, i.e. the trench-crossed M1 lines. This embodiment provides that (1) SW1 is <5 times LW1 and <5 times LW2, (2) SW2 is <5 times LW2 and <5 times LW3 and (3) SW3 is ≧5 times LW3 and ≧5 times LW4. It is therefore found that M1 lines 116, 118 and 120 are dense lines, while M1 line 122 is an isolated line. Lines 116 and 118 and 120 are designated selected dense M1 lines The expressions “selected dense M1 line” and “selected dense interconnect M1 line” as used within the context of the present invention mean a trench-crossed M1 line that is a dense line.

With reference to FIG. 1A, IC structure 100 includes a dense line subset 137 that includes dense lines 116, 118 and 120. The expression “dense line subset” as understood in the context of the present invention means that each selected dense M1 line of the subset is adjacent to at least one other selected dense M1 line of this dense line subset.

As shown in FIG. 1A, M1 line 116 includes a vertical side surface 123 such that side surface 123 (1) is positioned between substrate 110 and etch stop layer 130 and (2) faces away from dense line subset 137. M1 line 120 includes a vertical side surface 125 such that side surface 125 (1) is positioned between substrate 110 and etch stop layer 130 and (2) faces away from the subset. Dense line subset 137 includes vertical side surfaces 123 and 125.

IC structure 100, shown in FIG. 1A, is completed by forming a conventional first etch mask layer, such as a photoresist layer 139, on third dielectric layer 134.

IC structure 140, illustrated in FIG. 1B, is formed by patterning and developing first resist layer 136 to form a first trench etch mask 142 including a trench etch pattern 143 and a trench etch pattern 144. Trench etch patterns 143 and 144 overlay trench design XT1 and are in alignment therewith. A section 145 of resist layer 136 is retained between trench patterns 143 and 144. As shown in FIG. 1B, resist layer section 145 overlays dense line subset 137 comprising M1 interconnect lines 116, 118 and 120. Section 145 extends beyond subset 137 by extending beyond lines 116 and 120, i.e. extending beyond vertical side surfaces 123 and 125 of dense line subset 137. Resist layer section 145 extends a tolerance space TS1 beyond side surface 123 of subset 137. Similarly, section 145 extends a tolerance space TS2 beyond side surface 125 of subset 137, see FIG. 1B. In the context of the present invention the expression “tolerance space” means the dielectric space that is provided between a dielectric layer extending horizontally beyond one or more underlying interconnect lines, and that forms the dielectric space for electrical isolation between an electrically conductive shunt and underlying interconnect lines, which will be described in more detail in connection with IC structures 274 (FIG. 1J) and 320 (FIG. 1M). As depicted in FIG. 1B, TS1 is the dielectric space between (1) vertical plane 148 of end surface 146 of section 145 and (2) vertical plane 149 of side surface 123 of subset 137. Similarly, TS2 is the dielectric space between (1) vertical plane 150 of end surface 147 of section 145 and (2) vertical plane 151 of side surface 125 of subset 137. Tolerance spaces of the present invention typically range from 40 nm to 100 nm, but are not limited to this range.

The width of trench etch patterns 143 and 144 (FIG. 1B), is substantially equal to the width of the M2 interconnect line that will be described in connection with FIG. 1N. It is further noted that the width of any cavity, interconnect line or shunt is a dimension measured in a horizontal direction and perpendicular to the length dimension of the interconnect line or shunt that will be formed as shown in FIG. 1N. Returning to FIG. 1B, the terms “horizontal” and “horizontally” as used herein denote a plane that is substantially parallel to top the surface of a substrate, such as top surface 112 of semiconductor substrate 110. The terms “vertical” and “vertically” as used herein denote a plane that is substantially perpendicular to the top surface of a substrate, such as top surface 112 of semiconductor substrate 110. The terms “substantial” or “substantially” as used herein mean at least 90% of the relevant 100%. Trench etch pattern 144 overlays and crosses interconnect line 122. In connection with IC structure 140 (FIG. 1B), it is further noted that trench patterns 143 and 144 do not extend to end surface designs XE1 and XE2 respectively of trench design XT1 shown in FIG. 1A.

With reference to FIG. 1C, IC structure 153 is fabricated by employing conventional anisotropic etching procedures and using trench etch patterns 143 and 144 to simultaneous form a shunt slots 154 and 156 respectively, wherein shunt slots 154 and 156 extend through second and third dielectric layer 132 and 134 respectively. This etching procedure does not substantially etch the etch stop layer 130. In connection with shunt slot 154 it is noted that this shunt slot includes a shunt slot bottom portion 155 that is formed in second dielectric layer 132. Similarly, shunt slot 156 includes a shunt slot bottom portion 157 that is formed in second dielectric layer 132. Also, shunt slot 154 includes shunt slot top portion 158 that is formed in third dielectric layer 134, while shunt slot 156 includes shunt slot top portion 159 that is formed in third dielectric layer 134. Shunt slot 154 (FIG. 1C) does not extend to end surface design XE1 of trench design XT1. Shunt slot 156 does not extend to design end surface XE2.

Following the etch procedure for forming shunt slots 154 and 156, first trench etch mask 142 is removed as illustrated in FIG. 1D, depicting IC structure 160 including shunt slots 154 and 156. The etch procedure also results in forming (1) a dielectric stack 162, (2) a dielectric stack 164 and (3) a dielectric stack 166. Each of dielectric stacks 162, 164 and 166 include two dielectric layers i.e. second dielectric layer 132 comprising the bottom layer and third dielectric layer 134 comprising the top layer of each of these dielectric stacks. Dielectric stacks 162, 164 and 166 include top surfaces 170, 172 and 174 respectively. Shunt slot 154 is positioned between dielectric stacks 162 and 164 while shunt slot 156 is positioned between dielectric stacks 164 and 166. As illustrated in FIG. 1D, dielectric layer 134 of stack 162 includes a vertical end surface 182 facing shunt slot 154. Dielectric layer 134 of stack 164 includes (1) a vertical end surface 184 facing shunt slot 154 as well as extending beyond end surface 123 of subset 137, and (2) a vertical end surface 186 facing shunt slot 156 as well as extending beyond end surface 125 of subset 137. Similarly, dielectric layer 134 of stack 166 has a vertical end surface 188 facing shunt slot 156. Tolerance spaces TS1 and TS2 are retained in dielectric stack 164, see FIG. 1D, since end surfaces 184 and 186 respectively are fabricated by means of end surfaces 146 and 147 respectively of resist layer section 145 (FIG. 1B).

With reference to IC structure 160, shown in FIG. 1D, portion 190 of etch stop layer 130 is positioned underneath shunt slot 154, while portion 192 of etch stop layer 130 is positioned underneath shunt slot 156. Portion 192 of etch stop layer 130 is thus positioned on interconnect line 122, between interconnect line 122 and shunt slot 156. As shown in FIG. 1D, dielectric stack 164 includes (1) a top layer 194 comprising a portion of dielectric layer 134 and (2) a bottom layer 195 comprising a portion of dielectric layer 132. Bottom layer 195 includes (1) vertical end surface 196 extending beyond side surface 123 of subset 137 and (2) vertical end surface 197 extending beyond side surface 125 of subset 137.

Subsequently, IC structure 200 shown in FIG. 1E is fabricated by depositing a sacrificial fill 210, in shunt slots 154 and 156, and additionally forming a layer or overburden 212 of sacrificial fill on top surfaces 170, 172 and 174 of dielectric stacks 162, 164 and 166 respectively. Preferably, top surface 214 of sacrificial fill overburden 212 is planarized.

Sacrificial fill 210 comprises materials having dissimilar etching characteristics with respect to (1) etch stop layer 130 and (2) second dielectric layer 132.

As illustrated in FIG. 1F, IC structure 220 is formed by depositing a conventional second etch mask layer, such as a photoresist layer 222, on top surface 214 of sacrificial fill 210. Then, as shown in FIG. 1G, IC structure 226 is fabricated by patterning and developing second resist layer 222 to form a second trench etch mask 228. This etch mask includes trench etch patterns 230 and 232, each having a width that is substantially the same as the width of trench etch patterns 143 and 144 respectively of IC structure 140 depicted in FIG. 1B. Returning to FIG. 1G, trench etch patterns 230 and 232 overlay, and are in alignment with, underlying shunt slots 154 and 156 respectively that are filled with sacrificial fill 210. Trench etch pattern 230 includes vertical end surfaces 234 and 236. End surface 234 of trench etch pattern 230 is positioned on the sacrificial overburden that overlays dielectric stack 162, while end surface 236 of trench etch pattern 230 is positioned on the sacrificial fill overlaying shunt slot 156. Preferably, distance D1 between vertical plane 237 of end surface 236 of trench etch pattern 230, and end surface 186 of dielectric stack 164 typically ranges from 10 nm to 100 nm, but is not limited to this range, in order to allow for metal process misalignment. This distance can be incorporated in the process design rules for a standard stream file format such as GDS-II.

Trench etch pattern 232 of IC structure 226 (FIG. 1G) includes vertical end surfaces 238 and 240. Vertical end surface 238 is positioned on the sacrificial overburden overlaying second shunt slot 156. Preferably, distance D2 between vertical end surface 188 of dielectric stack 166 and vertical plane 239 of end surface 238 of trench etch pattern 232 is about 10 to about 100 nanometer to allow for metal process misalignment. As depicted in FIG. 1G, vertical end surface 240 of IC structure 226 is positioned on the sacrificial fill on dielectric stack 166. It is noted that trench etch pattern 230 overlays and crosses interconnect lines 116, 118 and 120 in first dielectric layer 114.

With reference to FIG. 1G, vertical end surface 234 of trench etch pattern 230 is positioned in vertical plane 241 of design end surface XE1, while vertical end surface 240 of trench etch pattern 232 is positioned in vertical plane 242 of design end surface XE2. Vertical end surface 234 of trench etch pattern 230 is thus in vertical alignment with design end surface XE1, while vertical end surface 240 of trench etch pattern 232 is in vertical alignment with design end surface XE2. Distance D3 between trench etch pattern end surfaces 234 and 240 is therefore substantially equal to design length XL1 (FIG. 1A) of trench design XT1.

IC structure 244, shown in FIG. 1H, is then fabricated by etching IC structure 226 (FIG. 1G) in order to open the sacrificial fill underneath trench etch patterns 230 and 232. This etching step exposes top surface 172 of dielectric stack 164. The etching step also exposes a portion 246 of top surface 170 of dielectric stack 162 underlying etch pattern 230. Similarly, this etching step exposes a top portion 248 of top surface 174 of dielectric stack 166 underlying trench etch pattern 232. As depicted in FIG. 1H, sacrificial fill 210 that is deposited in shunt slot 156 is etched in this etching step, thereby forming a gap 250 extending between end surface 236 of trench etch pattern 230 along vertical plane 237, and end surface 186 of dielectric stack 164. Also, sacrificial layer 210 that is deposited in shunt slot 156 is etched to form a gap 252 extending between end surfaces 238 along vertical plane 239 of trench etch pattern 232 and vertical end surface 188 of dielectric stack 166.

As depicted in FIG. 1I, IC structure 260 is fabricated by utilizing etch patterns 230 and 232 (FIG. 1G), to strip the sacrificial fill by etching the sacrificial fill that is exposed by etch patterns 230 and 232, and also to remove dielectric layer top portion 194 (comprising dielectric layer 134) from dielectric stack 164. Additionally, this etching step utilizes etch patterns 230 and 232 to remove, through etching, third dielectric layer 134 portions extending underneath portions 246 and 248 (FIG. 1H) of top surfaces 170 and 174 of dielectric stacks 162 and 166 respectively, thus forming vertical end surfaces 262 and 264 (FIG. 1I) in dielectric stacks 162 and 166 respectively. This etching step does not substantially etch second dielectric layer 132 and etch stop layer 130.

With reference to FIG. 1I, vertical end surfaces 262 and 264 of third dielectric layer 134 are aligned with vertical end surfaces 234 and 240 of trench etch patterns 230 and 232 respectively. Vertical end surface 262 is therefore positioned in layer 134 at design end surface XE1, while vertical end surface 264 is positioned in layer 134 at design end surface XE2.

The etching procedure that is employed to form IC structure 260, depicted in FIG. 1I, additionally extends gap 250 (FIG. 1H) to etch stop layer 130, thereby forming a gap 268 (FIG. 1I), while also extending gap 252 (FIG. 1H) to etch stop layer 130 thereby forming a gap 270 (FIG. 1I).

With reference to FIGS. 1I and 1J, a subsequent etching procedure is executed to open the exposed portions of etch stop layer 130 and to strip second trench etch mask 228, thereby fabricating IC structure 274 (FIG. 1J). IC structure 274 includes an extended shunt slot 276 that is formed such that extended shunt slot 276 includes shunt slot bottom portion 155 (FIGS. 1C and 1J) and opened portion 278 of etch stop layer 130, that is formed through removal (by etching) of portion 190 (FIG. 1I) of etch stop layer 130. Opened portion 278 (FIG. 1J) of etch stop layer 130 is aligned with shunt slot bottom portion 155. Additionally, slots 268 and 270 (FIG. 1I) are extended by opening underlying portions 271 and 272 respectively (FIG. 1I) of etch stop layer 130, thereby fabricating etch stop layer cavities 280 and 282 respectively (FIG. 1J), and forming a portion 284 of etch stop layer 130 underneath sacrificial fill 210.

As illustrated in FIG. 1J, the etching procedure also results in forming a portion 286 of etch stop layer 130 underneath bottom layer 195, wherein bottom layer 195 comprises (1) a portion of second dielectric layer 132 (FIG. 1D) and (2) the bottom layer of dielectric stack 164. Bottom layer 195 and etch stop layer portion 286 are positioned between extended shunt slot 276 and etch stop layer cavity 280. Tolerance spaces TS1 and TS2 are retained in bottom layer 195 and etch stop layer portion 286 as a consequence of the etching procedure for fabricating bottom layer 195 and etch stop layer portion 280. As shown in FIG. 1J, tolerance space TS2 adjoins etch stop layer cavity 280, thereby forming a cumulative tolerance space CTS1. The expression “cumulative tolerance space” as understood in the context of the present invention means a space that is formed by adding the tolerance space to the distance that is allowed for metal process misalignment. CTS1 is thus distance D1 (FIG. 1G) added to TS2 (FIG. 1J), i.e. about 50 nm to about 200 nm. Distances or spaces such as the distance that is allowed for metal process alignment and the tolerance space are typically defined in the design rules for fabricating reticles.

As depicted in FIG. 1K, showing IC structure 290, any remaining sacrificial fill 210 is removed by etching IC structure 274 (FIG. 1J), thereby opening shunt slot bottom portion 157. It will be understood that distance D4 between vertical end surfaces 262 and 264 (FIG. 1K) of dielectric layer 134, substantially equals distance D3 (FIG. 1G), because vertical end surfaces 262 and 264 of IC structure 290 are aligned with vertical end surfaces 234 and 240 respectively of IC structures 226 (FIG. 1G) and 260 (FIG. 1I). Additionally, distance D4 (FIG. 1K) substantially equals design length XL1 (FIG. 1A), because trench design length XL1 substantially equals length D3 (FIG. 1G), while distance D4 substantially equals distance D3 (FIG. 1G).

Returning to FIG. 1K, bottom portion 195 of second dielectric layer 132 is positioned between shunt slot bottom portions 155 and 157. Tolerance spaces TS1 and TS2 are retained in IC structure 290 because the etching procedure to fabricate IC structure 290 does not substantially etch bottom layer 195 and etch stop portion 286.

IC structure 290, as additionally illustrated in FIG. 1L, includes the following cavities: (1) an interconnect line trench cavity 300 extending horizontally between vertical end surfaces 262 and 264 of third dielectric layer 134, (2) shunt slot 276 extending underneath line trench cavity 300 and in alignment with trench cavity 300 and (3) a shunt slot 302 extending underneath line trench cavity 300 and in alignment therewith, wherein the shunt slot 302 includes (i) shunt slot bottom portion 157 and (ii) etch stop layer cavities 280 and 282 extending underneath shunt slot bottom portion 157 and in alignment with shunt slot bottom portion 157. Portions 304 and 306 of interconnect line trench cavity 300 comprise shunt slot top portions 158 (FIG. 1D) and 159 respectively. Shunt slots, also referred to as shunt cavities, 276 and 302 are open to trench cavity 300.

With respect to interconnect line trench cavity 300, depicted in FIG. 1L, end surfaces 262 and 264 of trench cavity 300 are positioned in third dielectric layer 134 at design end surfaces XE1 and XE2 respectively. It is therefore concluded that interconnect line trench cavity 300 is fabricated according to trench design XT1 shown in FIG. 1A.

As depicted in FIG. 1M, IC structure 320 illustrates fabricating dual damascene structure 322 including a shunted interconnect line 324. In this processing step, an electrically conductive material such as metal, for example copper, is deposited simultaneously in cavities 276 (FIG. 1L), 280, 282, 300, and 302 thereby forming an electrically conductive shunted interconnect line 324 (FIG. 1M) comprising (1) an electrically conductive horizontal interconnect line segment 326 extending horizontally between end surfaces 226 and 264 of third dielectric layer 134, (2) a first electrically conductive shunt 328 formed in cavity 276 (FIG. 1L) underneath horizontal interconnect line segment 326 (FIG. 1M) and (3) a second electrically conductive shunt 330 formed in cavity 302 (FIG. 1L) underneath horizontal interconnect line segment 326. Electrically conductive shunt 330 (FIG. 1M) additionally includes electrically conductive ridges 332 and 334 that are fabricated in etch stop layer cavities 280 and 282 (FIG. 1L) respectively. It is noted that shunts 328 and 330 (FIG. 1M) are aligned with horizontal interconnect line segment 326.

With reference to FIG. 1M, electrically conductive horizontal interconnect line segment 326 is fabricated in accordance with trench design XT1, since line segment 326 is fabricated in line trench cavity 300 (FIG. 1L) according to trench design XT1.

Returning to FIG. 1M, tolerance spaces TS1 and TS2 are retained in IC structure 320, see IC structure 274 depicted in FIG. 1J. These tolerance spaces provide the minimum allowed dielectric space between dense line subset 137 and conductive shunts 328 and 330 respectively, thus providing effective electrical insulation between the shunts and the interconnect lines of dense line subset 137 and shunted interconnect line 322.

FIG. 1N depicts a schematic perspective illustration of the electrically conductive components of IC structure 320 shown and described in connection with FIG. 1M. Length L1 of shunted interconnect line 324 (FIG. 1N) is substantially equal to distances D3 (FIG. 1G) and D4 (FIG. 1K) because line segment 326 of interconnect line 324 is fabricated between vertical end surfaces 262 and 264 of dielectric layer 134, see FIG. 1L, wherein vertical end surfaces 262 and 264 are fabricated in alignment with vertical end surfaces 234 and 240 respectively of trench etch patterns 230 and 232 (FIG. 1G).

Returning to FIG. 1N, width W1 of horizontal interconnect line segment 326 is substantially equal to width W2 of first conductive shunt 328 and to width W3 of second conductive shunt 320, since these conductive shunts are fabricated in alignment with horizontal interconnect line segment 326. It is noted that sidewall surface 335 of interconnect line segment 326 is substantially coplanar with sidewall surface 337 of conductive shunt 328 and with sidewall surface 338 of conductive shunt 330, as will be further described in connection with FIGS. 1U and 1V.

FIGS. 1O-1V are schematic illustrations to further show the positions of etching patterns and shunt slots that are designed and fabricated in the embodiment of the present invention depicted in FIGS. 1A-1L.

IC structure 140 depicted and described in connection with FIG. 1B is shown in plan view FIG. 1O. Etch patterns 143 and 144 are fabricated such that sidewall 340 of etch pattern 143 and sidewall 342 of etch pattern 144 are fabricated in plane 344. Similarly, sidewall 345 of etch pattern 143 and sidewall 348 of etch pattern 144 are fabricated in plane 350. Sidewall 340 is thus substantially coplanar with sidewall 342, while sidewall 345 is substantially coplanar with sidewall 348. In other words, a first sidewall of etch pattern 143 is substantially coplanar with a first sidewall of etch pattern 144, while a second sidewall of etch pattern 143 is substantially coplanar with a second sidewall of etch pattern 144.

IC structure 153 depicted and described in connection with FIG. 1C is shown in plan view FIG. 1P, depicting shunt slots 154 and 156 that are formed on etch stop layer 130. By analogy with plan view FIG. 10, IC structure 153 illustrates that sidewall 354 of shunt slot 154 and sidewall 356 of shunt slot 156 are substantially coplanar in plane 358. Similarly, sidewall 360 of shunt slot 154 and sidewall 362 of shunt slot 156 are substantially coplanar in plane 364. A first sidewall of slot 154 is thus substantially coplanar with a first sidewall of slot 156, while a second sidewall of slot 154 is substantially coplanar with a second sidewall of slot 156.

IC structure 226 depicted and described in connection with FIG. 1G is shown in plan view FIG. 1Q. Etch patterns 230 and 232 are formed in resist layer 222 on sacrificial overburden 210, such that sidewall 352 of pattern 230 is substantially coplanar with sidewall 354 of pattern 232 in plane 355 of IC structure 226. Similarly, sidewall 356 of pattern 230 is substantially coplanar with sidewall 357 of pattern 232 in plane 359 of IC structure 226. A first sidewall of etch pattern 230 is thus substantially coplanar with a first sidewall of etch pattern 232, while a second sidewall of pattern 232 is substantially coplanar with a second sidewall of pattern 232. FIG. 1Q additionally shows the positions of design end surfaces XE1 and XE2.

FIG. 1R shows a schematic cross-sectional view of IC structure 226, shown in FIG. 1Q, along the line X1-X1. Sidewall 352 of etch pattern 230 is substantially coplanar with sidewall 360 of shunt slot 154 that is filled with sacrificial fill 210, because pattern 230 is fabricated in alignment with underlying slot 154. Similarly, sidewall 356 of etch pattern 230 is substantially coplanar with sidewall 362 of slot 154.

A schematic cross-sectional view of IC structure 226, shown in FIG. 1Q, along the line X2-X2 is depicted in FIG. 1S. Sidewall 354 of etch pattern 332 is substantially coplanar with sidewall 364 of shunt slot 156 that is filled with sacrificial fill 210 because pattern 332 is fabricated in alignment with underlying slot 156. Similarly, sidewall 358 of pattern 332 is substantially coplanar with sidewall 366 of slot 156.

IC structure 290 depicted and described in connection with FIG. 1L is schematically shown in plan view FIG. 1T. Interconnect line trench cavity 300 extends in third dielectric layer 134 between end surfaces 262 and 264. Shunt slots 276 and 302 extend underneath line trench cavity 300 such that line trench cavity 300 is aligned with slots 276 and 302. As depicted in FIG. 1T, end surfaces 262 and 264 are fabricated on design end surfaces XE1 and XE2 respectively.

FIG. 1U shows a schematic cross-sectional view of IC structure 290, shown in FIG. 1T along the line X3-X3. Interconnect line trench cavity 300 (FIGS. 1T and 1U) includes sidewalls 372 and 374, such that sidewalls 372 and 374 extend along the entire sidewall of the trench cavity between end surfaces 262 and 264. With reference to FIG. 1U, shunt slot 276 includes sidewalls 376 and 378. Sidewall 372 of line trench cavity 300 is substantially coplanar with sidewall 376 of shunt slot 276 because (1) trench pattern 146 (FIG. 1C) is aligned with underlying shunt slot bottom portion 155 of shunt slot 154, (2) trench etch pattern 230 (FIG. 1G) is aligned with underlying shunt slot 154 that is filled with sacrificial fill 210, trench etch pattern 230 is therefore aligned with shunt slot bottom 154 and (3) shunt slot 276 (FIGS. 2K and 1L) includes a top portion comprising shunt slot bottom portion 155. The substantially coplanar relationship between sidewall 372 of line trench cavity 300 and sidewall 376 of shunt slot 276 results from the alignment between etch patterns and shunt slots that are enumerated immediately above. For the same reasons, sidewall 374 of line trench cavity 300 (FIG. 1U) is substantially coplanar with sidewall 378 of shunt slot 276.

FIG. 1V depicts a schematic cross-sectional view of IC structure 290, shown in FIG. 1T, along the line X4-X4. Returning to FIG. 1V, interconnect line trench cavity 300 includes sidewalls 372 and 374 as described in connection with FIG. 1U and as further depicted in FIG. 1T. Shunt slot 302, shown in FIG. 1V, includes sidewalls 380 and 382. By analogy with the above reasoning in connection with FIG. 1U, sidewall 372 (FIG. 1V) of trench cavity 300 is substantially coplanar with sidewall 380 of shunt slot 302, while sidewall 374 of trench cavity 300 is substantially coplanar with sidewall 382 of shunt slot 302. It is therefore reasoned that sidewalls 376 and 380 are substantially coplanar with sidewall 372 of trench cavity 300, while sidewalls 378 and 382 are substantially coplanar with sidewall 374 of trench cavity 300. IC structure 290, as illustrated in FIGS. 1T, 1U and 1V, thus includes first and second planes wherein (1) the first plane comprises a first sidewall of trench cavity 300 and sidewalls of shunt slots 276 and 302 such that these sidewalls are adjacent to the first sidewall of trench cavity 300, (2) the second plane comprises the second sidewall of trench cavity 300 and sidewalls of shunt slots 276 and 302 such that these sidewalls are adjacent to the second sidewall of trench cavity 300 and (3) the first and second trench sidewalls are opposing sidewalls. Examples of first and second sidewalls of trench cavity 300 include sidewalls 372 and 374 respectively, see FIG. 1T.

With reference to FIGS. 1N, 1U and 1V, it is shown that (1) sidewall surface 337 of conductive shunt 328 is fabricated on sidewall 378 of shunt slot 276, (2) sidewall surface 338 of conductive shunt 330 is fabricated on sidewall 382 of shunt slot 302 and (3) sidewall surface 335 of interconnect line segment 326 is fabricated on sidewall 374 of trench cavity 300. As described above in connection with FIGS. 1T, 1U and 1V, sidewalls 378, 382 and 374 are substantially coplanar. Consequently, sidewall surfaces 335 (FIG. 1N), 337 and 338 of shunted interconnect line 324 are substantially coplanar.

The techniques for forming shunted interconnect line 324 as described in connection with IC structures 100-320 and illustrated in FIGS. 1A-1V, are also suitable for forming a dual damascene structure including a shunted interconnect line with an underlying via, as described and illustrated in another embodiment of the present invention shown in FIGS. 2A-2N.

FIG. 2A shows an IC structure 400 having a semiconductor substrate 410, including a substrate top surface 412. A first dielectric layer 414 is formed on top surface 412 of substrate 410. Using methods and materials known to a person of ordinary skill in the art, electrically conductive interconnect lines 416, 418, 420, 422, 424 and 426 are fabricated in first dielectric layer 414, wherein line 426 is partly shown. M1 lines 418, 420, 422 and 424 are similar to M1 lines 116, 118, 120 and 122 respectively of IC structure 100, shown in FIG. 1A. M1 lines 418, 420, 422 and 424 are substantially parallel, similar to lines 116, 118, 120 and 122 of IC structure 100, illustrated in FIG. 1A.

Returning to FIG. 2A, an etch stop layer 430 is deposited on first dielectric layer 414 and on interconnect lines 416, 418, 420, 422, 424 and 426. Preferably, etch stop layer 430 has a minimum thickness that is substantially equal to 300 Å. Next, a second dielectric layer 432 is deposited on etch stop layer 430, thereafter a third dielectric layer 434 is deposited on second dielectric layer 432. It will be understood that the top surfaces of semiconductor substrate 410, first dielectric layer 414, etch stop layer 430, second dielectric layer 432 and third dielectric layer 434 are preferably planarized using conventional planarizing techniques, prior to forming a subsequent layer on each of these enumerated layers. IC structure 400 is completed by forming a conventional first etch mask layer, such as a photoresist layer 439, on third dielectric layer 434. First dielectric layer 414 is also referred to as metallizing layer 1 (M1), while third dielectric layer 434 is also referred to as metallizing layer 2 (M2). Second dielectric layer 432 is also referred to as via layer 1 (V1).

IC structure 400, illustrated in FIG. 2A comprises a dielectric stack 438 that includes layers 414, 430, 432 and 434, wherein layer 414 includes interconnect lines 416, 418, 420, 422, 424 and 426.

With reference to FIG. 2A, second and third dielectric layers 432 and 434 respectively, comprise materials having dissimilar etching characteristics. Etch stop layer 430 comprises materials having dissimilar etching characteristics with respect to (1) first dielectric layer 412, (2) second dielectric layer 432 and (3) third dielectric layer 434.

IC structure 400 (FIG. 2A) is similar to IC structure 100, shown in FIG. 1A, except that IC structure 400, includes an additional interconnect line, i.e. line 416, in the first dielectric layer.

In the following processing sequence, dielectric stack 438 is utilized (1) to fabricate an interconnect line trench cavity having an underlying via hole and two underlying shunt cavities, which will be described and illustrated in connection with FIG. 2L, and (2) to fabricate a shunted dual damascene interconnect line having two underlying electrically conductive shunts which will be described and illustrated in connection with FIG. 2M.

A trench design XT2 (FIG. 2A) is designed in third dielectric layer 434 such that trench design XT2 has end surface designs XE3 and XE4. Trench design XT2 crosses over M1 lines 416, 418, 420, 422 and 424, but does not cross over M1 line 426. Design length XL2 constitutes the length of trench design XT2. It is noted that XT2, XE3, XE4 and XL2 are design elements rather than fabricated elements. Trench design XT2 is designed for fabricating an interconnect line trench cavity 555 that will be illustrated and described in connection with IC structure 550 depicted in FIG. 2L.

Employing design information regarding trench design XT2 (FIG. 2A) in third dielectric layer 434, a determination is made to define which of the interconnect lines M1 lines 416, 418, 420, 422, 424 and 426 are isolated lines, if any, and which of these M1 lines are dense lines, if any. This determination is made according to the method for determining isolated and dense lines described in connection with M1 lines 116, 118, 120, 122 and 124 described and illustrated in connection with IC structure 100, shown in FIG. 1A.

For the purpose of defining interconnect lines as isolated or dense, the relevant line widths and dielectric spaces between the lines are determined as follows, as schematically shown in FIG. 2A. Line widths LW5, LW6, LW7, and LW8 indicate the line widths of interconnect lines 418, 420, 422 and 424 respectively. Similarly, (1) dielectric space width SW4 is the width of first dielectric layer 414 between lines 418 and 420, (2) dielectric space width SW5 is the width in layer 414 between lines 420 and 422, and (3) dielectric space width SW6 is the width in layer 414 between lines 422 and 424. These line widths and dielectric spaces are similar to the corresponding line widths and spaces of IC structure 100 illustrated in FIG. 1A.

Regarding M1 line 426, shown in FIG. 2A, it is noted that trench design XT2 does not cross over line 426, line 426 is therefore not included in a determination concerning isolated lines and dense lines.

In the embodiment of the present invention, illustrated in FIG. 2A, trench design XT2 provides that this trench design includes a trench bottom via connection position design XV2 for connecting the trench design to M1 line 416 at a subsequent processing step, see IC structure 550 shown in FIG. 2L. Where the processing sequence is designed to provide a via hole connection between M2 trench design XT2 and an underlying M1 line, the subject M1 line is designated as an M2-trench-connecting M1 line. As will be described in connection with IC structure 550 (FIG. 2L), design trench XT2 crosses over M1 line 416 while third via hole 532 forms a via hole connection between M1 line 416 and M2 trench design XT2 at trench bottom via connection position design XV1. M1 lines 418, 420 422 and 424 are therefore designated as trench-crossed M1 lines.

In the embodiment of the present invention shown in FIG. 2A, a design such as a CAD layout (not shown) or standard stream file format (not shown), e.g. GDS-II (not shown), provides the design information regarding M1 lines 418, 420, 422 and 424. This embodiment provides that (1) SW4 is <5 times LW5 and <5 times LW6, (2) SW5 is <5 times LW6 and <5 times LW7 and (3) SW6 is ≧5 times LW7 and ≧5 times LW8. It is therefore found that M1 lines 418, 420 and 422 are dense lines, while M1 line 424 is an isolated line. M1 lines 418, 420 and 422 are therefore designated as selected dense M1 lines.

With reference to FIG. 2A, IC structure 400 includes a dense line subset 423 that includes selected dense M1 lines 418, 420 and 422. Line 418 includes a vertical side surface 425 such that side surface 425 (1) is positioned between substrate 410 and etch stop layer 430 and (2) faces away from dense line subset 423. M1 line 422 includes a vertical side surface 427 such that side surface 427 (1) is positioned between substrate 410 and etch stop layer 430 and (2) faces away from the subset. Dense line subset 423 includes vertical side surfaces 425 and 427.

As depicted in FIG. 2B, IC structure 440 is formed by patterning and developing first resist layer 439 (FIG. 2A) to form a first trench etch mask 442 (FIG. 2B) including a via hole etch pattern 443 and trench etch patterns 444 and 445. Via hole pattern 443 overlays M1 line 416, while trench pattern 445 overlays isolated M1 line 424. A section 446 of resist layer 439 is retained between trench etch patterns 444 and 445. Vertical end surface 447 of section 446 extends beyond underlying side surface 425 of subset 423. Similarly, vertical end surface 448 of section 446 extends beyond underlying side surface 427 of dense line subset 423. Tolerance space TS3 between surfaces 447 and 425, as well as tolerance space TS4 between surfaces 448 and 427 are determined according to the method described in connection with tolerance spaces TS1 and TS2 respectively, illustrated in FIG. 1B.

Returning to FIG. 2B, the width of trench etch patterns 444 and 445 is substantially equal to the width of the M2 interconnect line that will be described in connection with FIG. 2N. Additionally, as shown in FIG. 2B, that via hole etch pattern 443 and trench etch pattern 445 do not extend to end surface designs XE3 and XE4 respectively of trench design XT2, shown in FIG. 2A. Via hole etch pattern 443 is formed in alignment with trench bottom via connection design XV1.

With reference to FIG. 2C, IC structure 450 is fabricated by employing conventional anisotropic etching procedures and using etch mask 442 to simultaneously form a first via hole 452, a shunt slot 454 and a shunt slot 456 in dielectric layers 432 and 434. This etching procedure does not substantially etch the etch stop layer 430. First via hole 452 and shunt slots 454 and 456 extend through dielectric layers 432 and 434. In connection with shunt slot 454 it is noted that this shunt slot includes a shunt slot bottom portion 455 that is formed in second dielectric layer 432. Similarly, shunt slot 456 includes a shunt slot bottom portion 457 that is formed in second dielectric layer 432. Also, shunt slot 454 includes shunt slot top portion 458 that is formed in third dielectric layer 434, while shunt slot 456 includes shunt slot top portion 459 that is similarly formed in third dielectric layer 434. Via hole 452 does not extend to design end surface XE3 of trench design XT2, while shunt slot 456 does not extend to design end surface XE4. Via hole 452 is aligned with trench bottom via connection design XV1, because via hole etch pattern 443 is aligned with trench bottom via connection design XV1.

Following the etch procedure for fabricating via hole 452 and shunt slots 454 and 456, first trench etch mask 442 is removed as illustrated in FIG. 2D, depicting IC structure 460 including first via hole 452 and shunt slots 454 and 456. The etch procedure also results in forming (1) a dielectric stack 462 positioned between first via hole 452 and shunt slot 454 (2) a dielectric stack 464 positioned adjacent via hole 452, (3) a dielectric stack 466 positioned between shunt slots 454 and 456 and (4) a dielectric stack 468 positioned adjacent second shunt slot 456. Each of dielectric stacks 462, 464, 466 and 468 include two dielectric layers, i.e. second dielectric layer 432 comprising the bottom layer and third dielectric layer 434 comprising the top layer. Dielectric stacks 462, 464, 466 and 468 include top surfaces 470, 472, 474 and 476 respectively.

Subsequently, IC structure 480 shown in FIG. 2E is fabricated by depositing a sacrificial fill 484, in first via hole 452, shunt slot 454 and in shunt slot 456, and additionally forming a layer or overburden 486 of sacrificial fill on top surfaces 470, 472, 474 and 476 of dielectric stacks 462, 464, 466 and 469 respectively. Preferably, top surface 487 of sacrificial fill overburden 486 is planarized.

Sacrificial fill 484 comprises materials having dissimilar etching characteristics with respect to (1) etch stop layer 430 and (2) second dielectric layer 432.

As illustrated in FIG. 2F, IC structure 490 is formed by depositing a conventional second etch mask layer, such as a photoresist layer 492, on sacrificial fill overburden 486. Then, as shown in FIG. 2G, IC structure 494 is fabricated by patterning and developing second resist layer 492 to form a second trench etch mask 495. This etch mask includes trench etch patterns 496 and 498, each having a width that is substantially the same as the width of trench etch patterns 444 and 445 of IC structure 440 depicted in FIG. 2B. Trench etch patterns 496 and 498 overlay, and are in alignment with, first via hole 452 and underlying shunt slots 454 and 456 (FIG. 2C) that are filled with sacrificial fill 484. Returning to FIG. 2G, trench etch pattern 496 includes a first end surface 500 and a second end surface 502. First end surface 500 is positioned on the sacrificial fill overlaying dielectric stack 464, while second end surface 502 is positioned on the sacrificial fill overlaying shunt slot 456.

End surface 500 of etch pattern 496 (FIG. 2G) is in vertical alignment with end surface design XE3 in dielectric layer 434 of dielectric stack 464, similar to the vertical alignment between end surface 234 (FIG. 1G) and design end surface XE1.

Preferably, distance D5 (FIG. 2G) between vertical plane 503 of second end surface 502 of etch trench pattern 496, and end surface 504 of dielectric stack 466 is about 10 nanometer to about 100 nanometer. Distance D5 is similar to distance D1 (FIG. 1G) to allow for metal process misalignment. With reference to FIG. 2G, it is noted that end surface 504 of dielectric stack 466, faces dielectric stack 468. Trench etch pattern 498 of IC structure 494 (FIG. 2G) includes first and second end surfaces 505 and 506 respectively. End surface 505 is positioned on the sacrificial fill overlaying shunt slot 456. End surface 506 of IC structure 494 is positioned on the sacrificial fill overlaying dielectric stack 468. End surface 506 of etch pattern 498 is in vertical alignment with end surface design XE4 in dielectric layer 434 of dielectric stack 468, similar to the vertical alignment between end surface 240 (FIG. 1G) and design end surface XE2.

Preferably, distance D6 (FIG. 2G) between vertical plane 507 of end surface 505 of trench etch pattern 498, and end surface 509 of dielectric stack 468 is about 10 nanometer to about 100 nanometer. Distance D6 is similar to distance D2 (FIG. 1G). Returning to FIG. 2G, distance D7 between end surfaces 500 and 506 of trench etch patterns 496 and 498 respectively is substantially equal to the length of the M2 interconnect line that will be described and illustrated in connection with FIG. 2N.

IC structure 510, shown in FIG. 2H, is then fabricated by etching IC structure 494 (FIG. 2G) in order to open the sacrificial fill underneath trench etch patterns 496 and 498. This etching step exposes top surfaces 470 and 474 (FIG. 2H) of dielectric stacks 462 and 466 respectively. The etching step also exposes portion 512 of top surface 472 of dielectric stack 464 underlying trench etch pattern 496 (FIG. 2G). Similarly, this etching step exposes top portion 514 of top surface 476 of dielectric stack 468 underlying trench etch pattern 498. As depicted in FIG. 2H, sacrificial layer 484 that is deposited in shunt slot 456, is etched in this etching step thereby forming a gap 517 extending between end surface 502 of etch pattern 496, and end surface 504 of dielectric stack 466. Also, sacrificial layer 484 that is deposited in shunt slot 456 is etched to form a gap 515 extending between end surfaces 505 and 506, see FIG. 2H. During this etching step, gap 515 is further extended between end surface 505 of etch pattern 498 (FIG. 2H) and end surface 516 of dielectric stack 468. It is noted that end surface 516 faces end surface 504 of dielectric stack 466.

In a subsequent etching step, described in connection with IC structure 520 shown in FIG. 2I, trench etch patterns 496 and 498 are utilized to strip the sacrificial fill that is exposed by etch patterns 496 and 498 (FIG. 2G) and also to remove dielectric layer 434 form dielectric stacks 462 and 466. Additionally, this etching step utilizes trench etch patterns 496 and 498 to remove third dielectric layer 434 portions 518 and 519 extending underneath top surface portions 512 and 514 (FIG. 2I) of dielectric stacks 464 and 468 respectively, thus forming vertical end surfaces 522 and 524 in dielectric stacks 464 and 468 respectively. This etching step does not substantially etch second dielectric layer 432 and etch stop layer 430.

With reference to FIG. 2I, it is noted that vertical end surfaces 522 and 524 of third dielectric layer 434 are aligned with vertical end surfaces 500 and 506 of trench etch mask patterns 496 and 498 respectively, while vertical end surfaces 500 and 506 are in vertical alignment with design end surfaces XE3 and XE4, see FIG. 2H. Vertical end surface 522 (FIG. 2I) is therefore positioned in layer 434 at design end surface XE3, and vertical end surface 524 is positioned in layer 434 at design end surface XE4.

The etching procedure that is employed to form IC structure 520, depicted in FIG. 2I, additionally extends gap 517 (FIG. 2H) to etch the etch stop layer 430, thereby forming a gap 526 (FIG. 2I), while also extending gap 517 through etch stop layer 430, resulting in a gap 528. Also, first via hole 452 (FIG. 2D) is reduced in height, to form a second via hole 529 extending through second dielectric layer 432, as shown in FIG. 2I.

With reference to FIGS. 2I and 2J, a subsequent etching procedure is executed to open the exposed portions of etch stop layer 430 and to strip the resist, thereby fabricating IC structure 530 (FIG. 2J). IC structure 530 includes a third via hole 532 extending through second dielectric layer 432 and through opened portion 533 of etch stop layer 430, thereby exposing third via hole 532 to underlying interconnect line 416. Additionally, a shunt slot 534 is formed such that shunt slot 534 includes shunt slot bottom portion 455 (FIGS. 2C and 2J) and opened portion 536 of etch stop layer 430 that is positioned underneath shunt slot bottom portion 455 and that is in alignment therewith. Additionally, gaps 526 and 527 (FIG. 2J) are extended by opening underlying portions 528 and 529 respectively (FIG. 2I) of etch stop layer 430, thereby fabricating etch stop layer cavities 538 and 540 respectively (FIG. 2J), and forming a portion 549 of etch stop layer 430 underneath sacrificial layer 484.

As depicted in FIG. 2K, showing IC structure 550, any remaining sacrificial layer 484 is removed by etching IC structure 530 (FIG. 2J), thereby opening shunt slot bottom portion 457. IC structure 550 includes (1) bottom layer 551 (comprising a section of second dielectric layer 432) having vertical end surfaces 552 and 553 and (2) a portion 554 of etch stop layer 430. Elements 423, 425, 427, 551, 552, 553, 554, TS3 and TS4 of IC structure 550 shown in FIG. 2K are similar to elements 137, 123, 124, 195, 196, 197, 286, TS1 and TS2 respectively of IC structure 290 depicted in FIG. 1K. Returning to FIG. 2K, it will be understood that distance D8 between vertical end surfaces 522 and 524 of IC structure 546 is substantially equal to distance D7 (FIG. 2G), because vertical end surfaces 522 and 524 are aligned with vertical end surfaces 500 and 506 respectively of IC structure 494 (FIG. 2G) and IC structure 520, shown in FIG. 2I. Additionally, distance D8 (FIG. 2K) substantially equals design length XL2 (FIG. 2A), because trench design length XL2 substantially equals length D7 (FIG. 2G), while distance D8 (FIG. 2K) substantially equals distance D7 (FIG. 2G).

IC structure 550, as additionally illustrated in FIG. 2L, includes the following cavities: (1) an interconnect line trench cavity 555 extending horizontally between end surfaces 522 and 524 of third dielectric layer 434, (2) the third via hole 532, also referred to as cavity 532, underneath line trench cavity 555, open to trench cavity 555 and in alignment therewith, and extending through (i) second dielectric layer 432 and (ii) etch stop layer 430, (3) shunt slot 534, also referred to as cavity 534, extending underneath line trench cavity 555 and in alignment therewith (4) a shunt slot 556, also referred to cavity 556, extending underneath line trench cavity 552 in alignment therewith, wherein shunt slot 556 includes (i) shunt slot bottom portion 457 extending through second dielectric layer 432 and (ii) etch stop layer cavities 538 and 540 extending underneath shunt slot bottom portion 457 and in alignment therewith, see FIG. 2L. Portions 557 and 558 of interconnect line trench cavity 555 comprise shunt slot portions 458 (FIGS. 2C and 2L) and 459 respectively. Interconnect line trench cavity 555 is connected to M1 line 416 by means of via hole 532, wherein via hole 532 is fabricated according to trench bottom via connection design XV1.

With respect to interconnect line trench cavity 555, depicted in FIG. 2L, end surfaces 522 and 524 are positioned in third dielectric layer 434 (i.e. layer M2) at design end surfaces XE3 and XE4 respectively. It is therefore concluded that interconnect line trench cavity 555 is fabricated according to line trench design XT2 shown in FIG. 2A.

By analogy with the description and illustrations in connection with FIGS. 1K, 1L and 1O-1V, IC structure 550, shown in FIGS. 2K and 2L includes first and second planes wherein (1) the first plane comprises a first sidewall of trench cavity 555 and sidewalls of shunt slots 534 and 556 such that these sidewalls are adjacent to the first sidewall of trench cavity 555, (2) the second plane comprises a second sidewall of trench cavity 555 and sidewalls of shunt slots 534 and 556 such that these sidewalls are adjacent to the second sidewall of trench cavity 552 and (3) the first and second trench sidewalls are opposing sidewalls.

IC structure 560 illustrates fabricating a dual damascene structure 562 as depicted in FIG. 2M. In this step, an electrically conductive material such as metal, for example copper, is deposited simultaneously in cavities 555 (FIG. 2L), 532, 534 and 556. Returning to FIG. 2M, dual damascene structure 562 includes (1) a shunted interconnect line 564 comprising (i) an interconnect line segment 565 formed in line trench cavity 552 (FIG. 2L) between end surfaces 522 and 524 of third dielectric layer 434 (FIG. 2M), (ii) a first electrically conductive shunt 566 (FIG. 2M) formed in shunt slot cavity 534 (FIG. 2L) underneath horizontal interconnect line segment 565, and (iii) a second electrically conductive shunt 568 (FIG. 2M) formed in cavity 556 (FIG. 2L) underneath horizontal interconnect line segment 565 (FIG. 2M) and (2) a via plug 569 fabricated in third via hole 532 (FIG. 2L) and extending underneath horizontal interconnect line segment 565 (FIG. 2M). Via plug 569 provides an electrically conductive connection between shunted interconnect line 564 and underlying interconnect line 416 in first dielectric layer 414. Within the context of the present invention, line 416 can also be referred to as an “M2-line-connected M1 line”, particularly in connection with a structure such as IC structure 560, shown in FIG. 2M. In those IC structures of the present invention wherein an M1 interconnect line is provided with an electrically conductive connection to a shunted interconnect line, the subject M1 line is referred to as an “M2-line-connected M1 line”.

FIG. 2N depicts a schematic perspective illustration of the electrically conductive components of IC structure 560 shown and described in connection with FIG. 2M. Returning to FIG. 2N, length L2 of shunted interconnect line 564 is substantially equal to distances D7 (FIG. 2G) and D8 (FIG. 2K) because line 564 is fabricated between vertical end surfaces 522 and 524, see FIG. 2L, that are in alignment with etch mask vertical end surfaces 500 and 506 of distance D7 of IC structure 494 depicted in FIG. 2G.

Returning to FIG. 2N, width W4 of horizontal interconnect line segment 562 is substantially equal to width W5 of first conductive shunt 566 and to width W6 of second conductive shunt 568, since these conductive shunts are fabricated in alignment with horizontal interconnect line segment 564.

Shunted interconnect line 564, shown in FIG. 2N, additionally includes (1) sidewall surface 572 of interconnect line segment 564, (2) sidewall surface 574 of conductive shunt 566 and (3) sidewall surface 576 of conductive shunt 568. By analogy with sidewall surfaces 335, 337 and 338 of shunted interconnect line 324 (FIG. 1N), it is concluded that sidewall surfaces 572 (FIG. 2N), 574 and 576 respectively, are substantially coplanar.

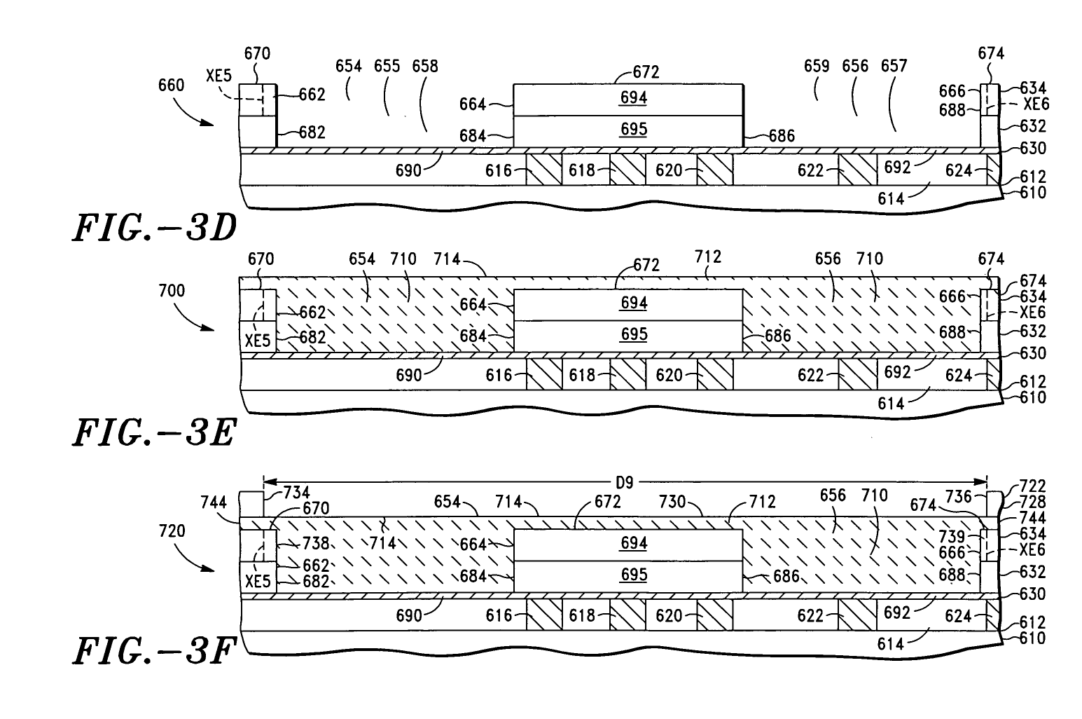

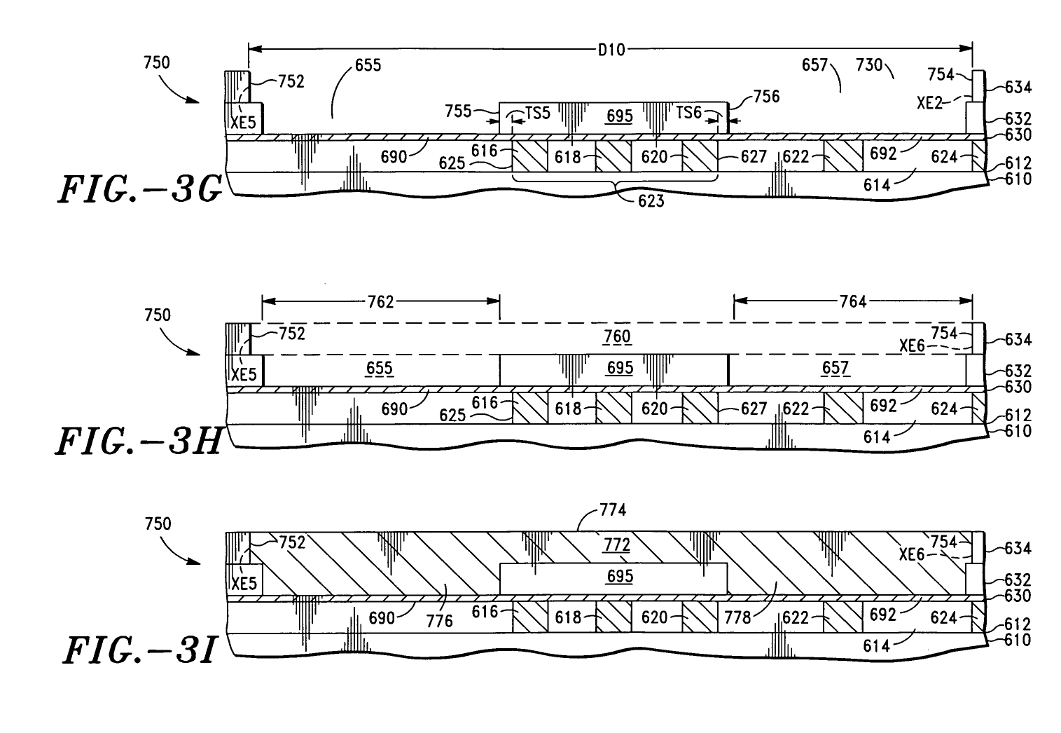

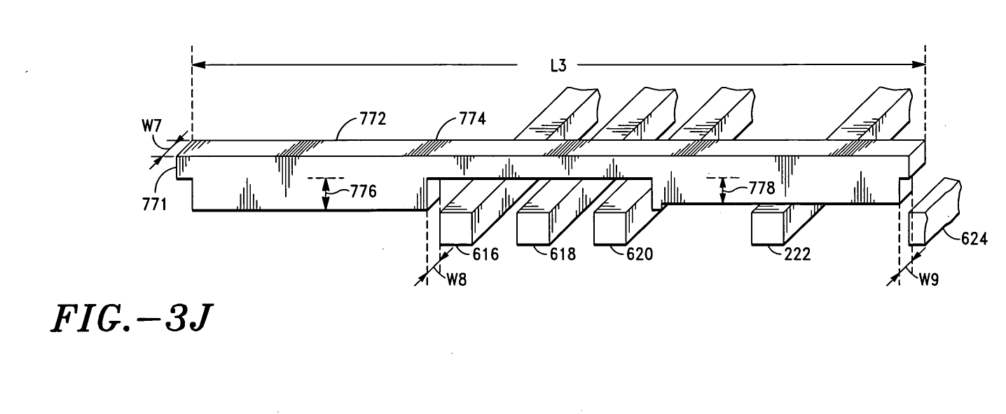

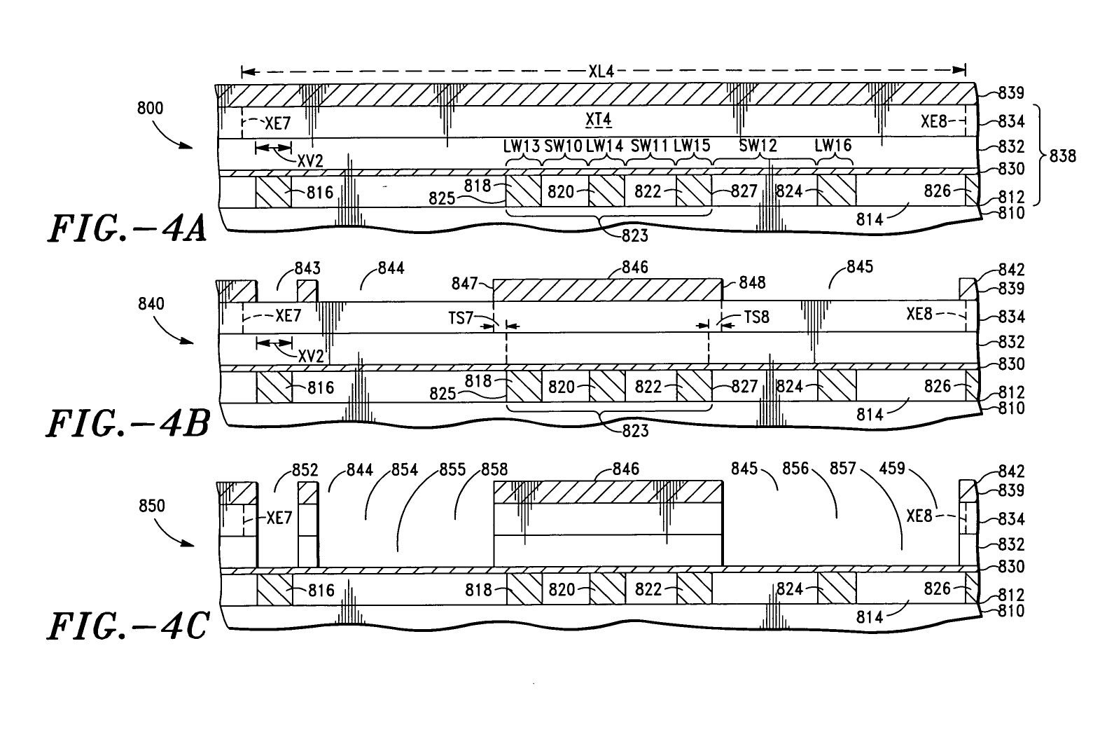

An additional embodiment of the invention, schematically illustrated in FIGS. 3A-3J, shows a novel additional processing sequence, for forming IC structures including IC structures comprising an interconnect line including electrically conductive shunts that are in alignment with the interconnect line.

FIG. 3A shows an IC structure 600 having a semiconductor substrate 610, including a substrate top surface 612. A first dielectric layer 614 is formed on top surface 612 of substrate 610. Using methods and materials known to a person of ordinary skill in the art, electrically conductive interconnect lines 616, 618, 620, 622 and 624 are fabricated in first dielectric layer 614, wherein line 624 is partly shown. Thereafter, an etch stop layer 630 is deposited on first dielectric layer 614 and on interconnect lines 616, 618, 620, 622 and 624. Preferably, etch stop layer 630 has a minimum thickness that is substantially equal to 300 Å. Next, a second dielectric layer 632 is deposited on etch stop layer 630, thereafter a third dielectric layer 634 is deposited on second dielectric layer 632. First and third dielectric layers 614 and 634 are also referred to as metallizing layers 1 (M1) and 2 (M2) respectively, while second dielectric layer 632 is also referred to as via layer 1 (V1). Top surfaces of semiconductor substrate 610, first dielectric layer 614, etch stop layer 630, second dielectric layer 632 and third dielectric layer 634 are preferably planarized using conventional planarizing techniques, prior to forming a subsequent layer on each of these enumerated layers. IC structure 600 is completed by forming a conventional first etch mask layer, such as a photoresist layer 639, on third dielectric layer 634.

With reference to IC structure 600 depicted in FIG. 3A, a dielectric stack 638 includes dielectric layers 614, 630, 632 and 634, wherein first dielectric layer 614 includes interconnect lines 616, 618, 620, 622 and 624.

Second and third dielectric layers 632 and 634 respectively, comprise materials having dissimilar etching characteristics. Etch stop layer 630 comprises materials having dissimilar etching characteristics with respect to (1) first dielectric layer 614, (2) second dielectric layer 632 and (3) third dielectric layer 634.

In the following processing sequence, dielectric stack 638 is utilized to (1) fabricate an interconnect line trench cavity having two underlying shunt cavities, which will be described and illustrated in connection with FIG. 3H, and (2) a shunted interconnect line having two underlying electrically conductive shunts which will be described and illustrated in connection with FIG. 3I.

A trench design XT3 (FIG. 3A) is designed in third dielectric layer 634 such that trench design has end surface designs XE5 and XE6. Trench design XT3 crosses over M1 lines 616, 618, 620 and 622, but does not cross over M1 line 624. Design length XL3 constitutes the length of trench design XT3. It is noted that XT3, XE5, XE6 and XL3 are design elements rather than fabricated elements. Trench design XT3 is designed for fabricating an interconnect line trench cavity 760 which will be described and illustrated in connection with IC structure 750 shown in FIG. 3H. Returning to FIG. 3A, M1 lines 616, 618, 820 and 622 are designated as trench-crossed M1 lines.

Employing design information regarding trench design XT3 (FIG. 3A) in third dielectric layer 434, a determination is made to define which of the interconnect lines M1 lines 616, 618, 620 and 622 are isolated lines, if any, and which of these M1 lines are dense lines, if any. This determination is made according to the method for determining isolated and dense lines described in connection with M1 lines 116, 118, 120, 122 and 124 described and illustrated in connection with IC structure 100, shown in FIG. 1A, and in connection with M1 lines 416, 418, 420, 422, 424 and 426 illustrated and described in connection with IC structure 400, depicted in FIG. 2A.

For the purpose of defining interconnect lines as isolated or dense, the relevant line widths and dielectric spaces between the lines are determined as follows, as schematically shown in FIG. 3A. Line widths LW9, LW10, LW11 and LW12 indicate the line widths of interconnect lines 616, 618, 620 and 622 respectively. Similarly, (1) dielectric space width SW7 is the width of first dielectric layer 614 between lines 616 and 618, (2) dielectric space width SW8 is the width in layer 614 between lines 618 and 620, and (3) dielectric space width SW9 is the width in layer 614 between lines 620 and 622. These line widths and dielectric spaces are similar to the corresponding line widths and spaces of IC structure 100 illustrated in FIG. 1A.

Regarding M1 line 624 (FIG. 3A), trench design XT3 does not cross over line 624, line 624 is therefore not designated as a trench-crossed M1 line. IC structure 600 (FIG. 3A) is similar to IC structure 100 (FIG. 1A).

In the embodiment of the present invention shown in FIG. 3A, a design such as a CAD layout (not shown) or standard stream file format (not shown), e.g. GDS-II (not shown), provides the design information regarding M1 lines 616, 618, 620 and 622. This embodiment provides that (1) SW7 is <5 times LW9 and <5 times LW10, (2) SW8 is <5 times LW10 and <5 times LW11 and (3) SW9 is ≧5 times LW11 and ≧5 times LW12. It is therefore found that M1 lines 616, 618 and 620 are dense lines, while M1 line 622 is an isolated line. M1 lines 616, 618 and 620 are designated as selected M1 lines.

With reference to FIG. 3A, IC structure 600 includes a dense line subset 623 that includes selected dense M1 lines 616, 618 and 620. Line 616 includes a vertical side surface 625 such that side surface 625 (1) is positioned between substrate 610 and etch stop layer 630 and (2) faces away from dense line subset 623. M1 line 620 includes a vertical side surface 627 such that side surface 627 (1) is positioned between substrate 610 and etch stop layer 630 and (2) faces away from dense line subset 623. Dense line subset 623 includes vertical side surfaces 625 and 627.

As illustrated in FIG. 3B, IC structure 640 is formed by patterning and developing first resist layer 639 to form a first trench etch mask 642 including trench etch patterns 643 and 644. A section 645 of resist layer 639 is retained between trench etch patterns 643 and 644. Vertical end surface 646 of section 645 extends beyond underlying side surface 625 of subset 623. Similarly, vertical end surface 647 of section 645 extends beyond underlying side surface 627 of subset 623. Tolerance space TS5 is determined as the dielectric space between vertical plane 648 of vertical end surface 646 and vertical plane 649 of side surface 625. Similarly, tolerance space TS6 is determined as the dielectric space between vertical plane 650 of vertical end surface 647 and vertical plane 651 of side surface 627. The method for determining tolerance spaces TS5 and TS6 is the same as the method for determining tolerance spaces TS1 and TS2 of IC structure 140 depicted in FIG. 1B.

Returning to FIG. 3B, the width of trench etch patterns 643 and 644 is substantially equal to the width of the interconnect line that will be described in connection with FIG. 3J. As illustrated in FIG. 3B, etch pattern 644 overlays and crosses interconnect line 622, while section 645 overlays M1 lines 616, 618 and 620. Trench etch patterns 643 and 644 do not extend to end surface designs XE5 and XE6 respectfully, see FIG. 3B. It is observed that IC structure 640 (FIG. 3B) is similar to IC structure 140 (FIG. 1B).

With reference to FIG. 3C, IC structure 652 is fabricated by employing conventional anisotropic etching procedures and using trench etch patterns 643 and 644 to simultaneous form a shunt slots 654 and 656 respectively, wherein shunt slots 654 and 656 extend through second and third dielectric layers 632 and 634 respectively. This etching procedure does not substantially etch the etch stop layer 630. In connection with shunt slot 654 it is noted that this shunt slot includes a shunt slot bottom portion 655 that is formed in second dielectric layer 632. Similarly, shunt slot 656 includes a shunt slot bottom portion 657 that is formed in second dielectric layer 632. Also, shunt slot 654 includes shunt slot top portion 658 that is formed in third dielectric layer 634, while shunt slot 656 includes shunt slot top portion 659 that is formed in third dielectric layer 634. As shown in FIG. 3C shunt slots 654 and 656 do not extend to design end surfaces XE5 and XE6 respectively. IC structure 652 (FIG. 3C) is similar to IC structure 153 (FIG. 1C).

Following the etch procedure for forming shunt slots 654 and 656 shown in FIG. 3C, first trench etch mask 642 is removed as illustrated in FIG. 3D, depicting IC structure 660 including shunt slots 654 and 656. The etch procedure also results in forming (1) a dielectric stack 662, (2) a dielectric stack 664 and (3) a dielectric stack 666. Each of dielectric stacks 662, 664 and 666 include two dielectric layers i.e. second dielectric layer 632 comprising the bottom layer and third dielectric layer 634 comprising the top layer. Dielectric stacks 662, 664 and 666 include top surfaces 670, 672 and 674 respectively. Shunt slot 654 is positioned between dielectric stacks 662 and 664 while shunt slot 656 is positioned between dielectric stacks 664 and 666. As illustrated in FIG. 3D, dielectric layer 632 of stack 662 includes a vertical end surface 682 facing shunt slot 654. Dielectric layer 632 of dielectric stack 664 includes (1) a vertical end surface 684 facing shunt slot 654 and (2) a vertical end surface 686 facing shunt slot 656. Similarly, dielectric layer 632 of dielectric stack 666 has a vertical end surface 688 facing shunt slot 656.

With reference to IC structure 660, shown in FIG. 3D, portion 690 of etch stop layer 630 is positioned underneath shunt slot 654, while portion 692 of etch stop layer 630 is positioned underneath shunt slot 656. Portion 692 of etch stop layer 630 is thus positioned on interconnect line 622, between interconnect line 622 and shunt slot 656. As shown in FIG. 3D, dielectric stack 664 includes (1) a top layer 694 comprising a portion of dielectric layer 634 and (2) a bottom layer 695 comprising a portion of dielectric layer 632. It is observed that IC structure 660 (FIG. 3D) is similar to IC structure 160 (FIG. 1D).

Subsequently, IC structure 700 shown in FIG. 3E is fabricated by depositing a sacrificial fill 710 in shunt slots 654 and 656, and additionally forming a layer or overburden 712 of sacrificial fill on top surfaces 670, 672 and 674 of dielectric stacks 662, 664 and 666 respectively. Preferably, top surface 714 of sacrificial fill overburden 712 is planarized. It is observed that IC structure 700 (FIG. 3E) is similar to IC structure 200 (FIG. 1E).

Sacrificial fill 710 comprises materials having dissimilar etching characteristics with respect to (1) etch stop layer 630 and (2) second dielectric layer 632.

As illustrated in FIG. 3F, IC structure 720 is formed by depositing a conventional second etch mask layer such as photoresist layer 722 on top surface 714 of sacrificial fill 710. Resist layer 722 is similar to resist layer 222 of IC structure 220, illustrated in FIG. 1F. Returning to FIG. 3F, second resist layer 722 is patterned and developed to form a second trench etch mask 728. This etch mask includes a trench etch pattern 730 having a width that is substantially the same as the width of trench etch patterns 646 and 648 of IC structure 640 depicted in FIG. 3B. Returning to FIG. 3F, trench etch pattern 730 overlays, and is in alignment with, underlying shunt slots 654 and 656 that are filled with sacrificial fill 710. Trench etch pattern 730 includes vertical end surfaces 734 and 736. End surface 734 of trench etch pattern 730 is positioned on the sacrificial overburden that overlays dielectric stack 662, while end surface 736 of trench etch pattern 730 is positioned on the sacrificial overburden overlaying third dielectric stack 666.

As depicted in FIG. 3F, end surface 734 of trench etch pattern 730 is in vertical alignment with end surface design XE5 in dielectric layer 434 of dielectric stack 662, similar to the vertical alignment between end surface 234 (FIG. 1G) and design end surface XE1. Similarly, end surface 736 (FIG. 3F) of trench etch pattern 730 is in vertical alignment with end surface design XE6 in dielectric layer 434 of dielectric stack 666.

As shown in FIG. 3F, trench etch pattern 730 overlays top surface 672 of dielectric stack 664. Additionally, trench etch pattern 730 overlays portion 738 of dielectric layer 634 of dielectric stack 662. Similarly, trench etch pattern 730 overlays portion 739 of dielectric layer 634 of dielectric stack 666. Trench etch pattern 730 overlays and crosses interconnect lines 616, 618, 620 and 622 in first dielectric layer 614.

Distance D9 between vertical end surfaces 734 and 736 of trench etch pattern 730 (FIG. 3F) is substantially equal to the length of the interconnect line that will be described in connection with FIG. 3J.

IC structure 750, depicted in FIG. 3G, is then fabricated by using an etch sequence including: (1) employing trench etch pattern 730 to (i) remove sacrificial fill 710 (FIG. 3F) and sacrificial overburden 712 that is exposed by the trench etch mask, (ii) remove portion 694 of dielectric layer 634 of dielectric stack 664, (iii) remove portion 738 of dielectric layer 634 of dielectric stack 662, thereby forming a vertical end surface 752 of third dielectric layer 634 and (iv) remove portion 739 of dielectric layer 634 of dielectric stack 666, thereby forming a vertical end surface 754 of third dielectric layer 634, wherein end surface 752 faces end surface 754, (2) removing trench etch mask 728 (FIG. 3F) and (3) removing sacrificial overburden that was not exposed by trench etch pattern 730, i.e. sacrificial overburden such as portions 744 that are positioned underneath etch mask 728. This etch sequence does not substantially etch second dielectric layer 632 and etch stop layer 630. It is noted that vertical end surfaces 752 and 754 of IC structure 750 (FIG. 3G) are aligned with end surfaces 734 and 736 (FIG. 3F) respectively of trench etch pattern 730. It will be understood that distance D10 between vertical end surfaces 752 and 754 (FIG. 3G) of dielectric layer 634, substantially equals distance D9 (FIG. 3F) because end surfaces 734 and 736 of distance D9 are in alignment with end surfaces 752 and 754 of distance D10.

With reference to FIG. 3G, vertical end surfaces 752 and 754 of dielectric layer 634 are formed in vertical alignment with vertical end surfaces 734 (FIG. 3F) and 736 of trench etch mask 730 depicted in FIG. 3F. Also, vertical end surfaces 734 and 736 are in vertical alignment with design end surfaces XE5 and XE6. Vertical end surface 752 (FIG. 3G) is therefore positioned in layer 634 at design end surface XE5, and end surface 754 is positioned in layer 634 at design end surface XE6.

Bottom portion 695 of second dielectric layer 632 is positioned between shunt slot bottom portions 655 and 657, see FIG. 3G. Bottom portion 695 includes (1) vertical end surface 755 extending beyond subset side surface 625 and (2) vertical end surface 756 extending between subset side surface 627. Tolerance space TS5 positioned between end surface 755 and side surface 625 as well as tolerance space TS6 positioned between end surface 756 and side surface 627 are determined in a manner similar to the TS1 and TS2 determinations described and illustrated in connection with IC structure 290 depicted in FIG. 1K.

IC structure 750, as additionally illustrated in FIG. 3H, includes the following cavities: (1) an interconnect line trench cavity 760 extending horizontally between vertical end surfaces 752 and 754 of third dielectric layer 634, (2) a shunt slot 655 extending underneath line trench cavity 760 and in alignment therewith and (3) a shunt slot 657 extending underneath line trench cavity 760 and in alignment therewith. Shunt slots 655 and 657 are also referred to as cavities 655 and 657 respectively. Portions 762 and 764 of interconnect line trench cavity 760 comprise shunt slot top portions 658 (FIG. 3C) and 659 respectively.

FIG. 3I illustrates fabricating an IC structure 770 including a shunted interconnect line. In this processing step, an electrically conductive material such as metal, for example copper, is deposited simultaneously in cavities 655 (FIG. 3H), 657 and 760 thereby forming an electrically conductive shunted interconnect line 772 (FIG. 3I) comprising (1) an electrically conductive horizontal interconnect line segment 774 extending between end surfaces 752 and 754 of third dielectric layer 634, (2) a first electrically conductive shunt 776 formed in cavity 655 (FIG. 3H) underneath horizontal interconnect line segment 774 (FIG. 3I) and (3) a second electrically conductive shunt 778 formed in cavity 657 (FIG. 3H) underneath horizontal interconnect line segment 774 (FIG. 3I). Shunts 776 and 778 are aligned with horizontal interconnect line segment 774.

FIG. 3J depicts a schematic perspective illustration of the electrically conductive components of IC structure 770 shown and described in connection with FIG. 3I. Length L3 of shunted interconnect line 762 (FIG. 3J) is substantially equal to distances D9 (FIG. 3F) and D10 (FIG. 3G) because line segment 764 of shunted interconnect line 762 is fabricated between vertical end surfaces 752 and 754 of dielectric layer 634, see FIG. 3H, while vertical end surfaces 752 and 754 are fabricated in alignment with vertical end surfaces 734 and 736 respectively of trench etch pattern 730 (FIG. 3F).

By analogy with the description and illustrations provided in connections with FIGS. 1K, 1L and 1O-1V, it is noted that IC structure 750, shown in FIGS. 3G and 3H, includes first and second planes wherein (1) the first plane comprises a first sidewall of trench cavity 760 and sidewalls of shunt slots 655 and 657 such that these sidewalls are adjacent to the first sidewall of trench cavity 760, (2) the second plane comprises a second sidewall of trench cavity 760 and sidewalls of shunt slots 655 and 657 such that these sidewalls are adjacent to the second sidewall of trench cavity 760 and (3) the first and second trench sidewalls are opposing sidewalls.

Returning to FIG. 3J, width W7 of horizontal interconnect line segment 764 is substantially equal to width W8 of first conductive shunt 766 and to width W9 of second conductive shunt 768, since these conductive shunts are fabricated in alignment with horizontal interconnect line segment 764. Shunted interconnect line 762, shown in FIG. 3J, additionally includes (1) sidewall surface 771 of interconnect line segment 764, (2) sidewall surface 772 of conductive shunt 766 and (3) sidewall surface 774 of conductive shunt 768. By analogy with sidewall surfaces 335,337 and 338 of shunted interconnect line 324 (FIG. 1N), it is noted that sidewalls surfaces 771 (FIG. 3J), 772 aid 774 respectively, are substantially coplanar.

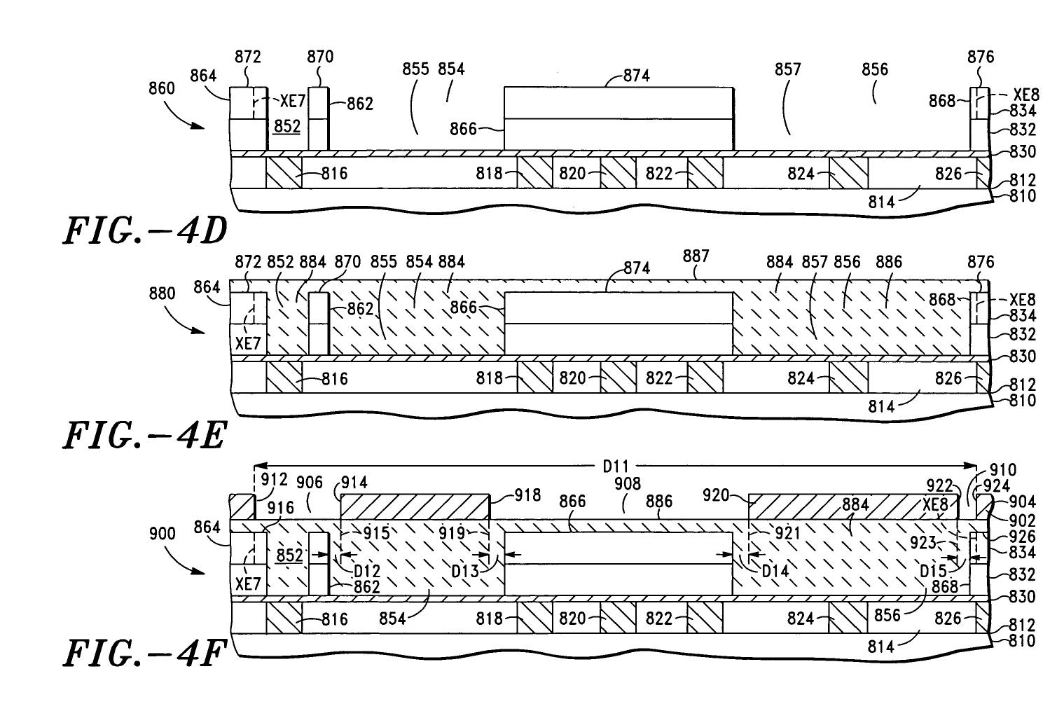

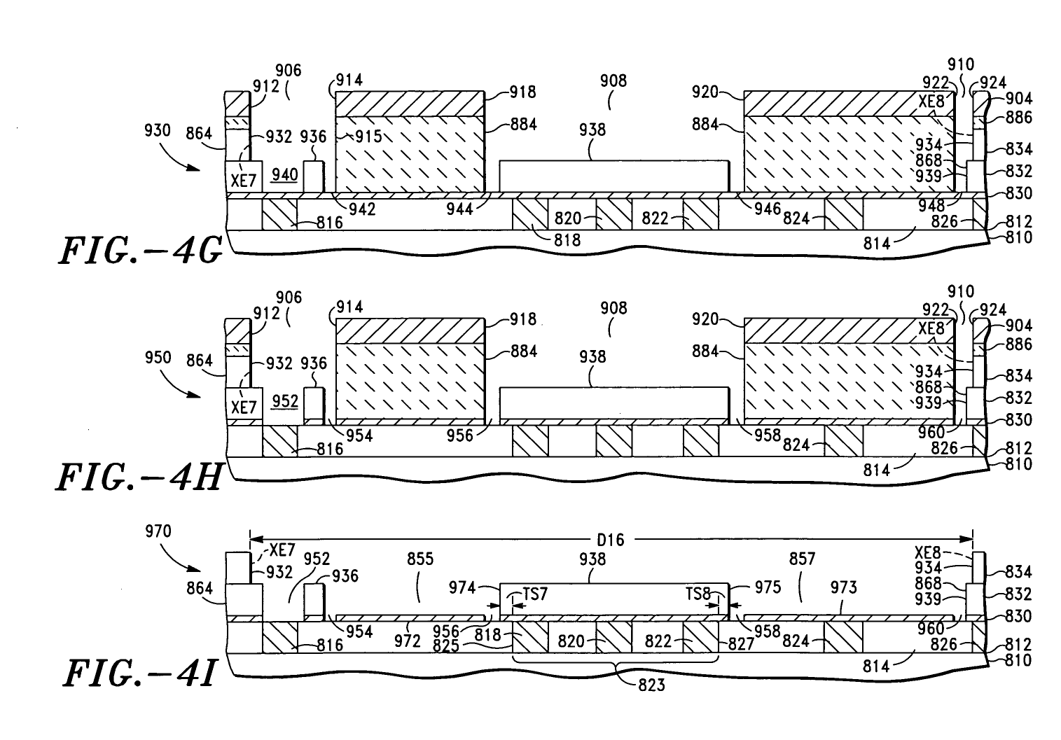

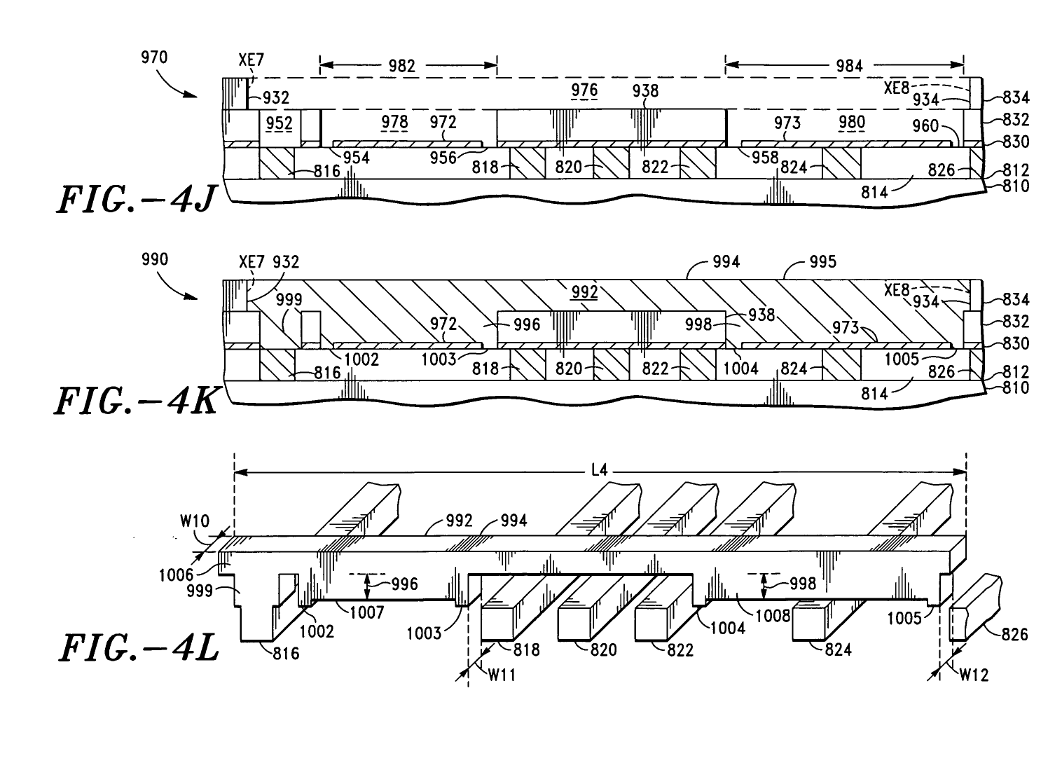

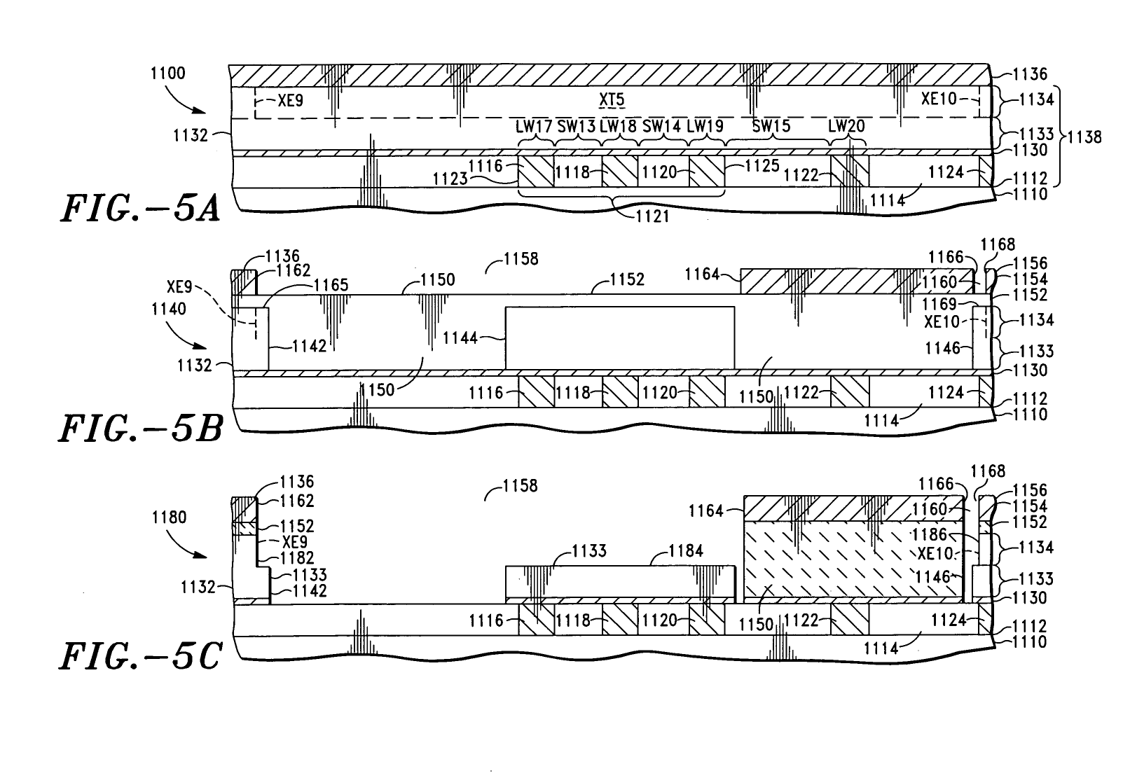

The techniques for forming shunted interconnect line 762 as described in connection with IC structures 600-770 and illustrated in FIGS. 3A-3J, are also suitable for forming a dual damascene structure including a shunted interconnect line with an underlying via, as described and illustrated in another embodiment of the present invention shown in FIGS. 4A-4L.

FIG. 4A shows an IC structure 800 having a semiconductor substrate 810, including a substrate top surface 812. A first dielectric layer 814 is formed on top surface 812 of substrate 810. Using methods and materials known to a person of ordinary skill in the art, electrically conductive interconnect lines 816, 818, 820, 822, 824 and 826 are fabricated in first dielectric layer 814, wherein line 826 is partly shown. Thereafter, an etch stop layer 830 is deposited on first dielectric layer 814 and on interconnect lines 816, 818, 820, 822, 824 and 826. Preferably, etch stop layer 830 has a minimum thickness that is substantially equal to 300 Å. Next, a second dielectric layer 832 is deposited on etch stop layer 830, thereafter a third dielectric layer 834 is then deposited on second dielectric layer 832. First and third dielectric layers 814 and 834 are also referred to as metallizing layers 1 (M1) and 2 (M2) respectively, while second dielectric layer 832 is also referred to as via layer 1 (V1). Top surfaces of semiconductor substrate 810, first dielectric layer 814, etch stop layer 830, second dielectric layer 832 and third dielectric layer 834 are preferably planarized using conventional planarizing techniques, prior to forming a subsequent layer on each of these enumerated layers. IC structure 800 is completed by forming a conventional first etch mask layer, such as a photoresist layer 839, on third dielectric layer 834.

Second and third dielectric layers 832 and 834 respectively, comprise materials having dissimilar etching characteristics. Etch stop layer 830 comprises materials having dissimilar etching characteristics with respect to (1) first dielectric layer 814, (2) second dielectric layer 832 and (3) third dielectric layer 834.

M1 lines 816, 818, 820, 822 and 824 are similar to M1 lines 416, 418, 520, 422 and 424 of IC structure 400, shown in FIG. 1A. M1 lines 818, 820, 822 and 824 are substantially parallel, similar to lines 418, 420, 422 and 424 of IC structure 400, depicted in FIG. 2A.

With reference to IC structure 800 depicted in FIG. 4A, a dielectric stack 838 includes dielectric layers 814, 830, 832 and 834, wherein first dielectric layer 814 includes interconnect lines 816, 818, 820, 822, 824 and 826.

In the following processing sequence, dielectric stack 838, depicted in FIG. 4A, is utilized to (1) fabricate an interconnect line trench cavity having and underlying via hole and two underlying shunt cavities, which will be described an illustrated in connection with FIG. 4J, and (2) a shunted dual damascene interconnect line having a via plug and two underlying electrically conductive shunts which will be described and illustrated in connection with FIG. 4K.

An interconnect line trench design XT4 (FIG. 4A) is designed in third dielectric layer 834 such that trench design XT4 has end surface designs XE7 and XE8. Trench design XT4 crosses over M1 lines 816, 818, 820, 822 and 824, but does not cross over M1 line 826. M1 lines 816, 818, 820, 822 and 824 are therefore designated as M2 trench-crossed M1 lines. Design length XL4 constitutes the length of trench design XT4. XT4, XE7, XE8 and XL4 are design elements rather than fabricated elements. Trench design XT4 is designed for fabricating an interconnect line trench cavity 976 that will be described and illustrated in connection with IC structure 970 shown in FIG. 4J. IC structure 800 (FIG. 4A) is similar to IC structure 400 (FIG. 2A).

Trench design XT4, shown in FIG. 4A, additionally includes a trench bottom via connection position design XV2. In a subsequent processing step, the trench bottom via connection position design will be employed to form a via hole connection between trench design XT4 and M1 line, see IC structure 970 illustrated in FIGS. 4I and 4J. M1 line 816 is therefore designated as an M2-trench-connecting M1 line, while M1 lines 818, 820, 822 and 824 are designated as trench-crossed M1 lines.

Employing design information regarding trench design XT4 (FIG. 4A) in third dielectric layer 834, a determination is made to define which of the M2 trench-crossed interconnect M1 lines 816, 818, 820, 822 and 824 are isolated lines, if any, and which of these M1 lines are dense lines, if any. This determination is made according to the method for determining isolated and dense lines described in connection with M1 lines 116, 118, 120, 122 and 124 described and illustrated in connection with IC structure 100, shown in FIG. 1A, and in connection with M1 lines 416, 418, 420, 422, 424 and 426 illustrated and described in connection with IC structure 400, depicted in FIG. 2A.

For the purpose of defining interconnect lines as isolated or dense, the relevant line widths and dielectric spaces between the lines are determined as follows, as schematically shown in FIG. 4A. Line widths LW13, LW14, LW15 and LW16 indicate the line widths of interconnect lines 818, 820, 822 and 824 respectively. Similarly, (1) dielectric space widths SW10 is the width of first dielectric layer 814 between lines 818 and 820, (2) dielectric space width SW11 is the width in layer 814 between lines 820 and 822, and (3) dielectric space width SW12 is the width in layer 814 between lines 822 and 824. These line widths and dielectric spaces are similar to the corresponding line widths and spaces of IC structure 100 illustrated in FIG. 1A.

In the embodiment of the present invention shown in FIG. 4A, a design such as a CAD layout (not shown) or standard stream file format (not shown), e.g. GDS-II (not shown), provides the design information regarding M1 lines 818, 802, 822 and 824. This embodiment provides that (1) SW10 <5 times LW13 and <5 times LW14, (2) SW11 is <5 times LW14 and <5 times LW15 and (3) SW12 is ≧5 times LW15 and ≧5 times LW16. It is therefore found that M1 lines 818, 820 and 822 are dense lines, while M1 lines 824 is an isolated line. Dense lines 818, 820 and 822 are therefore designated as selected M1 dense lines. Selected M1 dense lines form a dense line subset 823.

With reference to FIG. 4A, line 818 includes a vertical side surface 825 such that side surface 825 (1) is positioned between substrate 810 and etch stop layer 830 and (2) faces away from dense line subset 823. M1 line 822 includes a vertical side surface 827 such that side surface 827 (1) is positioned between substrate 810 and etch stop layer 830 and (2) faces away from the subset. Dense line subset 823 includes vertical side surfaces 825 and 827.

As depicted in FIG. 4B, IC structure 840 is formed by patterning and developing first resist layer 839 (FIG. 4A) to form a first trench etch mask 842 (FIG. 4B) including a via hole etch pattern 843 and trench etch patterns 844 and 845. Via hole etch pattern 843 is formed in alignment with trench bottom connection design XV2. A section 846 of resist layer 839 is retained between etch patterns 844 and 845. Vertical end surface 847 of section 846 extends beyond underlying side surface 825 of subset 823. Similarly, vertical end surface 848 of section 847 extends beyond underlying side surface 827 of subset 823. Tolerance space TS7 between surfaces 825 and 847, as well as tolerance space TS8 between surfaces 827 and 848 are determined according to the method described in connection with tolerance spaces TS1 and TS2 respectively, illustrated in FIG. 1B. IC structure 840 shown in FIG. 4B is similar to IC structure 440 depicted in FIG. 2B.

Returning to FIG. 4B, the width of trench etch patterns 844 and 845 (FIG. 4B), is substantially equal to the width of the interconnect line that will be described in connection with FIG. 4L.

With reference to FIG. 4C, IC structure 850 is fabricated by employing conventional anisotropic etching procedures and using etch mask 842 to simultaneously form a first via hole 852, a shunt slot 854 and a shunt slot 856 in dielectric layers 832 and 834. This etching procedure does not substantially etch the etch stop layer 830. First via hole 852 and shunt slots 854 and 856 extend through dielectric layers 832 and 834. In connection with shunt slot 854 it is noted that this shunt slot includes a shunt slot bottom portion 855 that is formed in second dielectric layer 832. Similarly, shunt slot 856 includes a shunt slot bottom portion 857 that is formed in second dielectric layer 832. Also, shunt slot 854 includes shunt slot top portion 858 that is formed in third dielectric layer 834, while shunt slot 856 includes shunt slot top portion 859 that is similarly formed in third dielectric layer 834. IC structure 850 is similar to IC structure 450 (FIG. 2C). Via hole 452 is aligned with trench bottom via connection design XV2, because via hole etch 452 is aligned with trench bottom via connection design XV1,

Following the etch procedure for fabricating shunt slots 854 and 856, first trench etch mask 842 is removed as illustrated in FIG. 4D, depicting IC structure 860 including first via hole 852 and shunt slots 854 and 856. The etch procedure also results in forming (1) a dielectric stack 862 positioned between first via hole 852 and shunt slot 854 (2) a dielectric stack 864 positioned adjacent via hole 852, (3) a dielectric stack 866 positioned between shunt slots 854 and 856 and (4) a dielectric stack 868 positioned adjacent shunt slot 856. Each of dielectric stacks 862, 864, 866 and 868 include two dielectric layers, i.e. second dielectric layer 832 comprising the bottom layer and third dielectric layer 834 comprising the top layer. Dielectric stacks 862, 864, 866 and 868 include top surfaces 870, 872, 874 and 876 respectively. IC structure 860 (FIG. 4D) is similar to IC structure 460 (FIG. 2D).

Subsequently, IC structure 880 shown in FIG. 4E is fabricated by depositing a sacrificial fill 884 in first via hole 852, shunt slot 854 and in shunt slot 856, and additionally forming a layer or overburden 886 of sacrificial fill on top surfaces 870, 872, 874 and 876 of dielectric stacks 862, 864, 866 and 869 respectively. Preferably, top surface 887 of sacrificial fill overburden 886 is planarized. IC structure 880 illustrated in FIG. 4E is similar to IC structure 480 shown in FIG. 2E

Sacrificial fill 884 (FIG. 4E) comprises materials having dissimilar etching characteristics with respect to (1) etch stop layer 830 and (2) second dielectric layer 832.

As illustrated in FIG. 4F, an IC structure 900 is formed by depositing a conventional second etch mask layer, such as a conventional photoresist layer 902, on sacrificial overburden 886. A second trench etch mask 904 is formed in etch mask layer 902. Etch mask 904 comprises (1) an etch mask section 906 overlaying via hole 852 that is filled with sacrificial fill 884, and dielectric stack 862 as well as partly overlaying dielectric stack 864, (2) an etch mask section 908 overlaying dielectric stack 866 and (3) an etch mask section 910 partly overlaying dielectric stack 868, see FIG. 4F. Etch mask section 906 includes vertical end surfaces 912 and 914, wherein end surface 912 overlays top surface 916 of dielectric stack 864, while end surface 914 overlays the sacrificial fill that is deposited in shunt slot 854. Etch mask section 908 includes vertical end surfaces 918 and 920, such that end surface 918 overlays the sacrificial fill in shunt slot 854 while end surface 920 overlays the sacrificial fill in shunt slot 856. Etch mask section 910 includes vertical end surfaces 922 and 924, wherein end surface 922 overlays the sacrificial fill in shunt slot 856 while end surface 924 overlays top surface 926 of dielectric stack 868.

As depicted in FIG. 4F, IC structure 900 includes second trench etch mask end surfaces 912, 914, 918, 920, 922 and 924. End surfaces 912 and 924 are formed at a distance D11 which is substantially equal to the length of the interconnect line that will be described in connection with FIG. 4L. Vertical plane 915 of end surface 914 of etch mask section 906 is positioned at a distance D12 from dielectric stack 862. Vertical planes 919 and 921 of end surfaces 918 and 920 respectively of etch mask section 908 are positioned at distances D13 and D14 respectively from dielectric stack 866. Additionally, vertical plane 923 of end surface 922 of etch mask section 910 is positioned at a distance D15 from dielectric stack 868. Preferably, each of distances D12, D13, D14 and D15 should be about 10 nm to about 100 nm to allow for metal process misalignment. IC structure 900 (FIG. 4F) is similar to IC structure 490 (FIG. 2F) except for the trench etch masks.

With reference to FIG. 4G, IC structure 930 is formed by anisotropically etching the sacrificial fill that is exposed underneath etch mask sections 906, 908 and 910 shown in FIG. 4F, as well as etching third dielectric layer 834 that is exposed underneath etch mask sections 906, 908 and 910 similar to the etch procedure described in connection with IC structures 510 and 520, shown in FIGS. 2H and 2I. The etching procedure illustrated in FIG. 4G is stopped by etch stop layer 830. IC structure 930 includes an end surface 932 of third dielectric layer 834 in dielectric stack 864, wherein end surface 932 is positioned underneath and in alignment with end surface 912 of etch mask section 906. Similarly, end surface 934 of dielectric layer 834 is formed in dielectric stack 868 such that end surface 934 is positioned underneath and in alignment with end surface 924 of etch mask section 910. The etching procedure for forming IC structure 930 also results in removal of layer 834 from dielectric stacks 862 and 866 (FIG. 4F) thereby forming dielectric layer 832 portions 936 and 938 respectively as shown in FIG. 4G. Additionally, the etching procedure causes the formation of third via hole 940 (FIG. 4G) in second dielectric layer 832 by partial removal of second via hole 852 (FIG. 4D).

Returning to FIG. 4G, the etching procedure for fabricating IC structure 930 additionally results in forming gaps 942, 944, 946 and 948 on etch stop layer 830. Gap 942 is formed between dielectric layer portion 936 and sacrificial fill that is aligned with vertical plane 915 of end surface 914 of etch trench mask section 906. It is noted that the width of gap 942 is substantially equal to D12 shown in FIG. 4F. Returning to FIG. 4G, gap 944 is formed between dielectric layer portion 938 and sacrificial fill that is aligned with end surface 918 of etch trench mask section 908. The gap width of gap 944 is substantially equal to D13 (FIG. 4F). Gap 946 (FIG. 4G) is formed between dielectric layer portion 938 and sacrificial fill that is aligned with end surface 920 of etch trench mask section 908. It is noted that the width of gap 946 is substantially equal to D14 shown in FIG. 4F. Gap 948, see FIG. 4G, is formed between sacrificial fill that is aligned with end surface 922 of second etch trench mask 904 and dielectric layer portion 939 of dielectric layer 832 of dielectric stack 868. The gap width of gap 948 is substantially equal to distance D15 depicted in FIG. 4F.

In a next etching procedure, using first dielectric layer 814 as an etch stop, exposed portions of etch stop layer 830 are etched in third via hole 940 (FIG. 4G) and gaps 942, 944, 946 and 948, thereby forming an IC structure 950 depicted in FIG. 4H, using techniques similar to those used in forming IC structure 530 (FIG. 2J). IC structure 950 (FIG. 4G) includes a fourth via hole 952 extending through second dielectric layer 832 and etch stop layer 830. Structure 950 further includes etch stop layer 830 cavities 954, 956, 958 and 960 that are formed by etching etch stop layer 830 that is exposed in gaps 942, 944, 946 and 948 respectively (FIG. 4G).

IC structure 970, illustrated in FIGS. 41 and 4J, is fabricated by removing second etch trench mask 904 (FIG. 4H) and any remaining sacrificial fill, using techniques similar to those described in connection with IC structures 530 and 550 shown in FIGS. 2J and 2K respectively. Structure 970 (FIG. 4I) includes a portion 972 of etch stop layer 830 that is positioned between cavities 954 and 956 as well as a portion 973 of etch stop layer 830 that is positioned between cavities 958 and 960. Etch stop layer cavity 954 is positioned between dielectric layer portion 936 and etch stop layer portion 972 while cavity 956 is positioned between etch stop layer portion 972 and dielectric layer portion 938. Cavity 958 is positioned between dielectric layer portion 938 and etch stop layer portion 973 while etch stop layer cavity 960 is positioned between etch stop layer portion 973 and dielectric layer portion 939.

As depicted in FIG. 4I, dielectric layer portion 938 includes (1) vertical end surface 974 extending beyond subset side surface 825 and (2) vertical end surface 975 extending beyond subset side surface 827. Tolerance space TS7 between end surface 974 and side surface 825 as well as tolerance space TS8 between end surface 975 and side surface 827 are determined in a manner similar to the TS1 and TS2 determinations described and illustrated in connection with IC structure 290 depicted in FIG. 1K.

Structure 970 shown in FIG. 4I, additionally includes shunt slot bottom portions 855 and 857 that are fabricated in a previous processing step shown in IC structure 850 depicted in FIG. 4C. Returning to FIG. 4I, it is noted that distance D16 between vertical end surfaces 932 and 934 in third dielectric layer 834 of IC structure 970 (FIG. 4I) is substantially equal to distance D11 of IC structure 900 (FIG. 4F) because end surfaces 912 and 924 of second trench etch mask 904 shown in FIG. 4F are vertically aligned with end surfaces 932 and 934 respectively of third dielectric layer 834 shown in FIG. 4I.

IC structure 970 (FIG. 4I) is similar to IC structure 550 (FIG. 2L), except that IC structure 970 retains an etch stop portion 972 that is not present in IC structure 550.

IC structure 970, as further illustrated in FIG. 4J, includes the following cavities: (1) an interconnect line trench cavity 976 extending horizontally between end surfaces 932 and 934 of third dielectric layer 834, (2) a fourth via hole 952 formed underneath line trench cavity 976 and extending through second dielectric layer 832 and through etch stop layer 830, (3) shunt slot 978 extending underneath line trench cavity 976 and in alignment with trench cavity 976, wherein shunt slot 978 includes (i) shunt slot bottom portion 855 (FIG. 4I) and (ii) etch stop layer cavities 954 and 956, (4) shunt slot 980 (FIG. 4J) extending underneath line trench cavity 976 and in alignment with trench cavity 976, wherein shunt slot 980 includes (i) shunt slot bottom portion 857 (FIG. 4I) and (ii) etch stop layer cavities 958 and 960. Portions 982 and 984 of interconnect line trench 976, shown in FIG. 4J, comprise shunt slot portions 858 and 859 respectively, depicted in FIG. 4C.

Interconnect line trench cavity 976 (FIG. 4J) is connected to M1 line 816 by means of via hole 952, wherein via hole 952 is fabricated according to trench bottom via connection design XV2.

By analogy with the description and illustrations provided in connection with FIGS. 1K, 1L and 1O-1V, it is noted that IC structure 970, shown in FIGS. 41 and 4J, includes first and second planes wherein (1) the first plane comprises a first sidewall of trench cavity 976 and sidewalls of shunt slots 978 and 980 such that these sidewalls are adjacent to the first sidewall of trench cavity 976, (2) the second plane comprises a second sidewall of trench cavity 976 and sidewalls of shunt slots 978 and 980 such that these sidewalls are adjacent to the second sidewall of trench cavity 976 and (3) the first and second trench sidewalls are opposing sidewalls.

IC structure 990 illustrates fabricating a dual damascene structure 992 as depicted in FIG. 4K. In this step, an electrically conductive material such as a metal, for example copper, is simultaneously deposited in cavities 976 (FIG. 4J), 952, 978 and 980. Returning to FIG. 4K, dual damascene structure 992 includes (1) a shunted interconnect line 994 comprising (i) an interconnect line segment 995 formed between end surfaces 932 and 934 of third dielectric layer 834, (ii) a first electrically conductive shunt 996 formed in shunt slot cavity 978 (FIG. 4J) underneath, and in alignment with, horizontal interconnect line segment 995 (FIG. 4K), and (iii) a second electrically conductive shunt 998 formed in shunt slot cavity 980 (FIG. 4J) underneath, and in alignment with horizontal interconnect line segment 995 (FIG. 4K) and (2) a via plug 999 (FIG. 4K) fabricated in fourth via hole 952 (FIG. 4J). Via plug 999 (FIG. 4K) provides an electrically conductive connection between shunted interconnect line 994 and underlying interconnect line 816 in first dielectric layer 814. Within the context of the present invention, line 816 can also be referred to as an “M2-line-connected M1 line”, particularly in connection with a structure such as IC structure 995, shown in FIG. 4K. Conductive shunt 996 (FIG. 4K) includes ridges 1002 and 1003 formed in etch stop layer cavities 954 (FIG. 4J) and 956, while conductive shunt 998 (FIG. 4K) includes ridges 1004 and 1005 formed in etch stop layer cavities 958 (FIG. 4J) and 960.

Dual damascene structure 992 shown in FIG. 4K is similar to dual damascene structure 562 illustrated in FIG. 2M, except that conductive shunt 996 (FIG. 4K) of dual damascene structure 992 includes an etch stop layer portion 972 positioned between ridges 1002 and 1003.

FIG. 4L depicts a schematic perspective illustration of the electrically conductive components of IC structure 990 shown and described in connection with FIG. 4K. Returning to FIG. 4L, length L4 of interconnect line segment 992 is substantially equal to distances D11 (FIG. 4F) and D16 (FIG. 41) because line segment 992 is fabricated between vertical end surfaces 932 and 934, see FIGS. 4J and 4K, wherein end surfaces 932 and 934 are fabricated in alignment with end surfaces 912 and 924 of trench etch mask 904 shown in FIG. 4F.

Returning to FIG. 4L, width W10 of interconnect line segment 992 is substantially equal to width W11 of first conductive shunt 996 and width W12 of second conductive shunt 998 because these conductive shunts are fabricated in alignment with line segment 992.

Shunted interconnect line segment 992, shown in FIG. 4L, additionally includes (1) sidewall surface 1006 of interconnect line segment 994, (2) sidewall surface 1007 of conductive shunt 996 and (3) sidewall surface 1008 of conductive shunt 998. By analogy with sidewall surfaces 335, 337 and 338 of shunted interconnect line 324 (FIG. 1N), it is noted that sidewall surfaces 1006, 1007 and 1008 (FIG. 4L) respectively, are substantially coplanar.

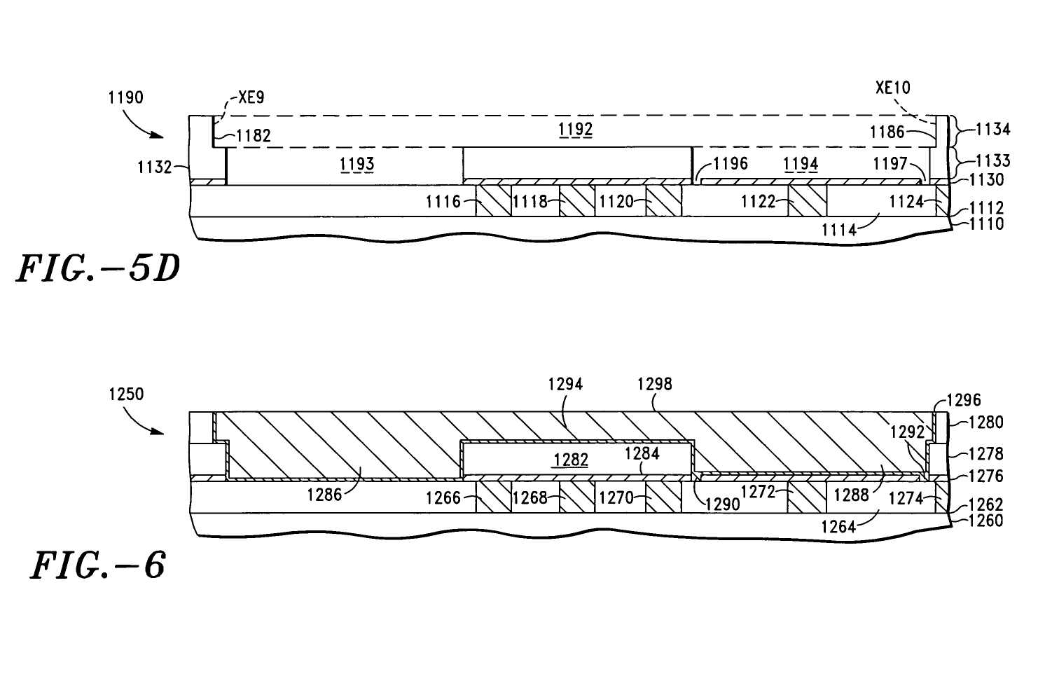

Embodiments of the present invention as illustrated and described in connection with FIGS. 1A-1V, 2A-2N, 3A-3J and 4A-4L include techniques for fabricating IC structures wherein M2 and V1 dielectric layers, having dissimilar etching characteristics, are sequentially deposited on an etch stop layer. However, techniques of the present invention are also suitable for fabricating IC structures wherein a single dielectric layer is deposited on an etch stop layer, instead of the M2 and V1 layers utilized in the above enumerated embodiments, such that the structure is fabricated through a timed etch technique as schematically illustrated and described in connection with FIGS. 5A-5D.

FIG. 5A shows an IC structure 1100 having a semiconductor substrate 1110 including a substrate top surface 1112. A first dielectric layer 1114 is formed on top surface 1112 of substrate 1110. Using methods and materials known to a person of ordinary skill in the art, electrically conductive interconnect lines 1116, 1118, 1120, 1122 and 1124 are fabricated in first dielectric layer 1114, wherein line 1124 is partly shown. Lines 1116, 1118, 1120 and 1122 are substantially parallel, similar to lines 116, 118, 120 and 122 of IC structure 100 shown in FIG. 1A. Returning to FIG. 5A, an etch stop layer 1130 is deposited on first dielectric layer 1114 and on interconnect lines 1116, 1118, 1120, 1122 and 1124. Next, a second dielectric layer 1132 is deposited on etch stop layer 1130. Top surface 1112 of semiconductor substrate 1110, and the top surfaces of first dielectric layer 1114, etch stop layer 1130 and second dielectric layer 1132 are preferably planarized using conventional planarizing techniques, prior to forming a subsequent layer on each of these enumerated layers.

Etch stop layer 1130 comprises materials having dissimilar etching characteristics with respect to (1) first dielectric layer 1114 and (2) second dielectric layer 132. Preferably, etch stop layer 1130 has a minimum thickness that is substantially equal to 300 Å.

IC structure 1100, shown in FIG. 5A, is completed by forming a conventional first etch mask layer, such as a photoresist layer 1136, on second dielectric layer 1132. Second dielectric layer 1132 includes a lower portion 1133 and an upper portion 1134. First dielectric layer 1114 is also referred to as metallizing layer 1 (M1) while upper portion 1134 of second dielectric layer 1132 is also referred to as metallizing layer 2 (M2). Lower portion 1133 of second dielectric layer 1132 is also referred to as via layer 1 (V1).

With reference to IC structure 1100 depicted in FIG. 5A, a dielectric stack 1138 includes layers 1114, 1130 and 1132, wherein (1) dielectric layer 1114 includes interconnect lines 1116, 1118, 1120, 1122 and 1124 and (2) dielectric layer 1132 includes a lower portion 133 and an upper portion 1134. In the following processing sequence, dielectric stack 1138 is utilized to (1) fabricate an interconnect line trench cavity having two underlying shunt cavities, that will be described and illustrated in connection with FIG. 5D.

An interconnect line trench design XT5 (FIG. 5A) is designed in upper dielectric layer portion 1134 such that trench XT5 has end surface designs XE9 and XE10. Trench design XT5 crosses over M1 lines 1116, 1118, 1120 and 1122, but does not cross over M1 line 1124. XT5, XE9 and XE10 are design elements rather than fabricated elements. Trench design XT5 is designed for fabricating an interconnect line trench cavity 1192 which will be illustrated and described in connection with IC structure 1190 depicted in FIG. 5D.

Employing information regarding trench design XT5 (FIG. 5A) in upper dielectric layer portion 1134, a determination is made to define which of the interconnect M1 lines 1116, 1118, 1120 and 1122 are isolated lines, if any, and which of these M1 lines are dense lines, if any. This determination is made according to the method for determining isolated an dense lines described in connection with M1 lines 116, 118, 120, 122 and 124 described and illustrated in connection with IC structure 100, shown in FIG. 1A.

For the purpose of defining interconnect lines as isolated or dense, the relevant line widths and dielectric spaces between the lines are determined as follows, as schematically shown in FIG. 5A. Line widths LW17, LW18, LW19 and W20 indicate the line widths of interconnect lines 1116, 1118, 1120 and 1122 respectively. Similarly, (1) dielectric space width SW13 is the width in first dielectric layer 1114 between lines 1116 and 1118, (2) dielectric space width SW14 is the width in layer 1114 between lines 1118 and 1120, and (3) dielectric space width SW15 is the width in layer 1114 between lines 1120 and 1122. These line widths and dielectric spaces are similar to the corresponding line widths and spaces of IC structure 100 illustrated in FIG. 1A. Regarding M1 line 1124, shown in FIG. 5A, trench design XT5 does not cross over line 1124, Lines 1116, 1118, 1120 and 1122 are designated as M2 trench crossed M1 layers.

In the embodiment of the present invention shown in FIG. 5A, a design such as a CAD layout (not shown) or standard stream file format (not shown), e.g. GDS-II (not shown), provides the design information regarding M1 lines 1116, 1118, 1120 and 1122. This embodiment provides that (1) SW13 is <5 times LW17 and <5 times LW18, (2) SW18 is <5 times LW18 and <5 times LW19 and (3) ≧5 times LW19 and ≧5 times LW20. It is therefore concluded that M1 lines 1116, 1118 and 1120 are dense lines, while M1 line 1122 is an isolated line. M1 lines 116 and 118 and 120 are thus designated as selected M1 dense lines. IC structure 1100 comprises a dense line subset 1121 that includes dense lines 1116, 1118 and 1120.

As shown in FIG. 5A, M1 line 1116 includes a vertical side surface 1123 such that side surface 1123 (1) is positioned between substrate 1110 and etch stop layer 1130 and (2) faces away from dense line subset 1121. M1 line 1120 includes a vertical side surface 1125 such that side surface 1125 (1) is positioned between substrate 1110 and etch stop layer 1130 and (2) faces away from the subset. Dense line subset 1121 includes vertical side surfaces 1123 and 1125.

As illustrated in FIG. 5B, an IC structure 1140 is fabricated by employing IC structure 1100 (FIG. 5A) and utilizing methods, materials and techniques similar to those used in sequentially fabricating IC structures 140 (FIG. 1B), 150 (FIG. 1C), 160 (FIG. 1D), 200 (FIG. 1E), 220 (FIG. 1F), and 226 (FIG. 1G).

Returning to FIG. 5B, IC structure 1140 includes dielectric stacks 1142, 1144 and 1146 of second dielectric layer 1132. Sacrificial fill 1150 is deposited between dielectric stacks 1142 and 1144 as well as between stacks 1144 and 1146. An overburden 1152 of sacrificial fill is deposited on dielectric stacks 1142, 1144 and 1146. Sacrificial fill 1150 comprises materials having dissimilar etching characteristics with respect to (1) etch stop layer 1130 and (2) second dielectric layer 1132.

Thereafter, a conventional second etch mask layer, such as a photoresist layer 1154 is deposited on sacrificial fill overburden 1152, as illustrated in FIG. 5B. The second resist layer is then patterned and developed to form a second etch mask 1156. This etch mask includes trench etch patterns 1158 and 1160, see FIG. 5B. Trench etch pattern 1158 includes vertical end surfaces 1162 and 1164, wherein end surface 1162 is positioned on the sacrificial overburden that overlays dielectric stack 1142, such that top portion 1165 of stack 1142 underlays etch pattern 1158. Trench etch pattern 1160 includes vertical end surfaces 1166 and 1168, wherein end surface 1168 is positioned on the sacrificial overburden overlaying dielectric stack 1146, such that top portion 1169 of stack 1146 underlays etch trench pattern 1160.

By analogy with IC structure 226, described and illustrated in connection with FIG. 1G, it is reasoned that end surface 1162 (FIG. 5B) of trench pattern 1158 is in substantial vertical alignment with end surface design XE9, while end surface 1168 of trench etch pattern 1160 is in substantial vertical alignment with end surface design XE10 (FIG. 5B) of trench etch design XT5, shown in FIG. 5A.

A comparison between IC structure 1140 (FIG. 5B) and IC structure 220 depicted in FIG. 1F shows that these structures are different only in the composition of the respective dielectric stacks of IC structure 1140 and IC structure 220. Dielectric stacks 1142, 1144 and 1146 of IC structure 1140 (FIG. 5B) are formed of second dielectric layer 1132 while dielectric stacks 162, 164 and 166 of IC structure 220 (FIG. 1E) are fabricated of second dielectric layer 132 and third dielectric layer 134.

IC structure 1140, shown in FIG. 5B is then etched to fabricate IC structure 1180 depicted in FIG. 5C. This etching procedure is used to remove sacrificial fill similar to the methods illustrated and described in connection with IC structures 244 and 260 shown in FIGS. 1H and 1I. Thereafter, a timed etch is executed, resulting in IC structure 1180 illustrated in FIG. 5C. The timed etch is executed such that only top portion 1165 of second dielectric layer 1132 is etched resulting in etching upper portion 1134 of dielectric stack 1142 such that end surface 1162 of etch pattern 1158 is extending through portion 1165 thereby forming end surface 1182 while not etching layer portion 1133. Regarding dielectric stack 1144 (FIG. 5D), the timed etch results in removing upper portion 1134 of stack 1144 thereby fabricating a dielectric stack 1184 that is formed of bottom portion 1133 of second dielectric layer 1132. The timed etch additionally causes dielectric stack 1146 to be etched such that end surface 1168 of trench etch pattern 1160 is extended through portion 1169 of second dielectric layer 1132, thereby forming end surface 1186 without etching layer portion 1133.

As depicted in FIG. 5D, IC structure 1190 is fabricated using techniques that are described and illustrated in connection with IC structure 290 shown in FIG. 1L. By analogy with FIG. 1L, IC structure 1190 illustrated in FIG. 5D includes the following cavities (1) an interconnect line trench cavity 1192 extending horizontally between end surfaces 1182 and 1186 of top portion 1134 of second dielectric layer 1132, (2) shunt slot 1193 extending underneath line trench cavity 1192 and in alignment therewith, and (3) shunt slot 1194 extending underneath line trench cavity 1192 and in alignment therewith, wherein shunt slot 1194 includes cavities 1196 and 1197 that are formed through etch stop layer 1130. By analogy with FIG. 1L, it is reasoned that end surface 1182 of trench cavity 1192 is positioned at design end surface XE9, while end surface 1186 of trench cavity 1192 is positioned at design end surface XE10 of trench etch design XT5, shown in FIG. 5A.

Using techniques similar to those employed in fabricating IC structure 320 shown in FIG. 1M, a shunted interconnect line (not shown) can be fabricated in cavities 1192, 1193 and 1194 of IC structure 1190 depicted in FIG. 5D.

Techniques for forming shunted interconnect lines, such as lines 324 (FIG. 1M), 564 (FIG. 2M), 762 (FIG. 3I) and 994 (FIG. 4K) include forming the shunted interconnect lines in dielectric cavities. It is known to a person of ordinary skill in the art to provide a Cu diffusion barrier layer between the Cu and the dielectric cavity wherein the Cu is deposited. Techniques of the present invention are suitable for fabricating shunted interconnect lines in dielectric cavities that are lined with a Cu diffusion barrier layer as illustrated and described in connection with FIG. 6.

IC structure 1250, depicted in FIG. 6, is fabricated by preparing an IC structure similar to IC structure 290 (FIG. 1L). Accordingly, elements 1260, 1262, 1264, 1266, 1268, 1270, 1272, 1274, 1276, 1278, 1280, 1282, 1284, 1286, 1288, 1290, 1292 and 1294 of IC structure 1250 shown in FIG. 6, are similar to elements 110, 112, 114, 116, 118, 120, 122, 124, 130, 132, 134, 195, 286, 276, 302, 280, 282 and 300 respectively of IC structure 290 depicted in FIG. 1L.

The fabricating steps are then continued by forming a Cu diffusion barrier layer 1296 in cavities 1286, 1288, 1290, 1292 and 1294, as shown in FIG. 6. Subsequently, Cu is deposited on barrier layer 1296, thereafter the structure is planarized to form shunted interconnect line 1298. Suitable materials for Cu diffusion barrier layer 1296 include conductors such as Ta, Ti and TiW. Instead of depositing a Cu diffusion barrier layer it is contemplated to fabricate a sandwich layer comprising (1) a Cu diffusion barrier layer that contacts the dielectric cavities and (2) a Cu seed layer that is formed on the Cu diffusion barrier layer.

While techniques for employing a Cu diffusion barrier layer or a barrier/seed sandwich layer (illustrated in FIG. 6) are exemplified in connection with shunted interconnect line 324 (FIG. 1M), it is also contemplated to employ these techniques in connection with shunted interconnect lines 564 (FIG. 2M), 762 (FIG. 3I) and 994 (FIG. 4K). It will be understood that Cu diffusion barrier layers in IC structures for shunted interconnect lines employing a via, for example dual damascene structures, require an electrically conductive barrier layer.

Etch mask layers of the present invention are exemplified by photoresist layers. However, it is also contemplated to use conventional hard mask and dual hard mask layers, using materials and techniques known to a person of ordinary skill in the art.

Etch stop layers of embodiments of the present invention, can provide an electrically insulating layer between an electrically conductive shunt and an underlying interconnect line. Illustrative examples of these etch stop layers include layers 130 (FIGS. 1A-1M), 430 (FIGS. 2A-2M), 630 (FIGS. 3A-3I), 830 (FIGS. 4A-4K) and 1130 (FIGS. 5A-5D). Preferably, the thickness of these above enumerated etch stop layers should have a minimum thickness that is substantially equal to 300 Å in order to (1) prevent an electrical short between the shunt and an underlying M1 interconnect line such as isolated line 122 (FIG. 1A) and (2) minimize or prevent cross talk and/or parasitic capacitance between the shunt and the interconnect line such as isolated line 122.

Examples of suitable materials for use in dielectric layers of the present invention such as layers 114, 132 and 134 (FIG. 1A) include silicon oxide. The expression “silicon oxide” as defined herein, includes SiO₂, related non-stoichiometric materials SiOₓ, related silica glasses include USGT (undoped silica glass), FSG (fluorinated silica glass), borophosphosilicate glass (BPSG) and C-doped silicon oxide. These dielectric materials have a low dielectric constant. Additionally other low dielectric constant materials are suitable for use in these layers, including for example amorphous fluorinated carbon based materials, spin-on dielectric polymers such as fluorinated and non-fluorinated poly(arylene) ethers (commercially known as FLARE 1.0 and 2.0, that are available from Allied Signal Company), poly(arylene) ethers (commercially known as PAE 2-3, available from Schumacher Company), divinyl siloxane benzocyclobutane (DVSOBCB) or similar products and aero-gel. Preferably, first and third dielectric layers such as layers 114 and 134 of IC structure 100 (FIG. 1A) include CH or CHF based polymetric dielectric materials. Second dielectric layers such as layer 132 of IC structure 100 preferably include SiOC or SiO₂.

Suitable materials for use in etch stop layers of embodiments of the present invention such as etch stop layer 130 of IC structure 100 (FIG. 1A) include, but are not limited to CVD SiN, SiC and SiCN.

Sacrificial fill materials suitable for use in embodiments of the present invention include but are not limited to organic and inorganic fill material that is deposited by conventional means such as spin-on or CVD (chemical vapor deposition). Conventional ARC (antireflective coating) material is a preferred organic fill material. Examples of ARC materials for use in embodiments of the present invention include but are not limited to organic ARC such as polyimide and inorganic ARC such as silicon oxynitrides and silicon oxycarbides.

Embodiments of the present invention as illustrated and described in connection with FIGS. 1A-1V, 2A-2N, 3A-3J, and 4A-4L comprise techniques for fabricating novel IC structures wherein interconnect lines are formed in metallizing layer 2 and wherein the interconnect lines include one or more electrically conductive shunts that are fabricated in via layer 1 underneath the interconnect line and in alignment therewith, such that the one or more shunts are contiguous with the interconnect line. The inventive conductive shunts reduce the electrical resistance of the interconnect line, thereby increasing signal and power transmission speed while also having the potential for lowering the IC operating temperature, compared to a similar interconnect line without the inventive electrically conductive shunts.

Tolerance spaces of the present invention such as TS1 and TS2 (FIGS. 1B, 1D, 1J, 1K and 2M) provide the minimum allowed dielectric space for electrical isolation between an electrically conductive shunt of an interconnect line, and underlying dense lines. Tolerance spaces of the present invention can be included in the design rules for fabricating IC structures such as IC chips, for example including the design rules in the stream file format for fabricating reticles. Optionally, IC design rules can be formulated for designing a cumulative tolerance space consisting of the sum of the tolerance space for isolation and the dielectric space/distance that is allowed for metal process misalignment, see for example cumulative tolerance space CTS1 illustrated in FIG. 1J.

Cumulative tolerance spaces of the present invention substantially prevent formation of a dielectric space between a shunt and an underlying dense line, or dense line subset, that is less than the intended minimum tolerance space.

Embodiments of the present invention illustrated and described in connection with FIGS. 1M, 1N, 2M, 1N, 3I, 3J, 4K, 4L and 6 concern shunted interconnect lines wherein the electrically conducting shunts overlay isolated lines but do not overlay dense lines. However, it is also contemplated to enhance the electrical isolation of the isolated lines by designing and fabricating shunted interconnect lines (not shown) wherein the shunts do not overlay the isolated lines, using similar techniques, involving tolerance spaces, as used in conjunction with the dense lines.

Regarding embodiments of the present invention as illustrated and described in connection with FIGS. 1A-1V, 2A-2N, 3A-3J. 4A-4L and 5A-5D, inventive techniques surprisingly require only two etch mask layers, such as etch mask layers 139 (FIG. 1A) and 222 (FIG. 1F) for fabricating shunted interconnect lines in M2 and V1 layers in a dielectric stack having M1 lines.

The invention has been described in terms of exemplary embodiments of the invention. One skilled in the art will recognize that it would be possible to construct the elements of the present invention from a variety of means and to modify the placement of components in a variety of ways. While the embodiments of the invention have been described in detail and shown in the accompanying drawings, it will be evident that various further modifications are possible without departing from the scope of the invention as set forth in the following claims.

I claim:

1. A method of fabricating an IC structure on a semiconductor substrate having a top surface, the method comprising:
a) fabricating a dielectric stack on the semiconductor substrate top surface by sequentially depositing (1) a first dielectric layer comprising a plurality of dense interconnect lines, (2) an etch stop layer, (3) a second dielectric layer and (4) a third dielectric layer;
b) preparing at least one interconnect line trench design in the third dielectric layer;
c) employing the at least one interconnect line trench design for identifying at least one dense line subset;
d) fabricating a third dielectric layer interconnect line trench according the interconnect line trench design; and
e) in the second dielectric layer, fabricating at least one shunt cavity (i) underlying the interconnect line trench, (ii) extending from the interconnect line trench to the etch stop layer and (iii) not crossing over the at least one dense line subset.

2. The method according to claim 1 wherein:
a) the etch stop layer and the first dielectric layer have dissimilar etching characteristics;
b) the second dielectric layer has dissimilar etching characteristics with respect to the etch stop layer and with respect to the first dielectric layer; and
c) the third dielectric layer has dissimilar etching characteristics with respect to the etch stop layer and with respect to the second dielectric layer.

3. The method of claim 1 wherein the at least one dense line subset is limited to dense lines that are positioned substantially parallel to each other.

4. The method of claim 1 wherein the at least one shunt cavity is positioned such that a tolerance space provides a minimum allowed space between the at least one shunt cavity and the at least one dense line subset.

5. The method of claim 4 wherein the tolerance space ranges from 40 nm to 100 nm.

6. The method of claim 1 wherein the at least one shunt cavity is positioned such that a cumulative tolerance space provides a minimum allowed dielectric space between the at least one shunt cavity and the at least one dense line subset.

7. The method of claim 1 wherein fabricating (i) the third dielectric layer interconnect line trench and (ii) the at least one shunt cavity comprises utilizing a total number of etch mask layers that is limited to two.

8. An IC structure fabricated according to the method of claim 2.

9. A method of fabricating an IC structure on a semiconductor substrate having a top surface, the method comprising:
a) fabricating a dielectric stack on the semiconductor substrate top surface by sequentially depositing (1) a first dielectric layer comprising a plurality of interconnect lines including (i) a plurality of dense interconnect lines and one (ii) or more isolated lines (2) an etch stop layer, (3) a second dielectric layer and (4) a third dielectric layer;
b) preparing at least one interconnect line trench design in the third dielectric layer;
c) employing the at least one interconnect line trench design, identifying (1) at least one dense line subset and (2) at least one isolated line that is positioned such that the interconnect line trench design crosses over (i) the at least one isolated line and (ii) the at least one dense line subset;
d) fabricating a third layer interconnect line trench according to the interconnect line trench design; and
e) fabricating at least a first shunt cavity (1) underlying the interconnect line trench, (2) extending from the interconnect line trench to the etch stop layer, (3) crossing over the at least one isolated line and (4) not crossing over the at least one dense line subset.

10. The method of claim 9 wherein the etch stop layer includes a minimum thickness that is substantially equal to 300 Å.

11. A method of fabricating an IC structure on a semiconductor substrate having a top surface, the method comprising:
a) fabricating a dielectric stack on the semiconductor substrate top surface by sequentially depositing (1) an M1 layer comprising a plurality of interconnect lines including (i) a plurality of dense interconnect lines and at least one M2-trench-connecting M1 line, (2) an etch stop layer, (3) a V1 layer and (4) an M2 layer;
b) preparing at least one interconnect line trench design in the M2 layer;
c) employing the at least one interconnect line trench design, identifying at least one dense line subset;
d) fabricating an M2 interconnect line trench, according to the interconnect line trench design;
e) fabricating a V1 via hole that connects the M2 interconnect line trench with the M2-line-connected M1 line; and
f) fabricating at least one shunt cavity (1) underlying the M2 interconnect line trench, (2) extending from the M2 interconnect line trench to the etch stop layer and (3) not crossing over the at least one dense line subset.

12. The method of claim 11 wherein the at least one shunt cavity is positioned such that a tolerance space provides a minimum allowed space between the at least one shunt cavity and the at least one dense line subset.

13. An IC structure fabricated according to the method of claim 11.

14. The method of claim 11 additionally comprising depositing an electrically conductive material simultaneously in (1) the M2 interconnect line trench, (2) the V1 via hole and (3) the at least one shunt cavity.
